(19) United States
(12) Patent Application Publication
(10) Pub. No.: US 2005/0258856 A1
(43) Pub. Date: Nov. 24, 2005

(54) High-speed interface circuit test module, module under high-speed interface circuit test, and high-speed interface circuit test method

(75) Inventors: Satoshi Kishimoto, Osaka-shi (JP); Tomohiko Kanemitsu, Toyonaka-shi (JP); Michio Maekawa, Takatsuki-shi (JP)

Correspondence Address: STEVENS, DAVIS, MILLER & MOSHER, LLP, 1615 L. STREET N.W., SUITE 850, WASHINGTON, DC, 20036, US

(73) Assignee: MATSUSHITA ELECTRIC INDUSTRIAL CO., LTD., Osaka (JP)

(21) Appl. No.: 11/133,290

(22) Filed: May 20, 2005

(30) Foreign Application Priority Data
May 24, 2004 (JP) 2004-153376

(51) Int. Cl. G01R 31/26

(52) U.S. Cl. 324/765

(57) ABSTRACT

In the shipment test of an LSI provided with a high-speed interface circuit, both cost reduction and a high test guarantee level are realized. The following are provided: a high-speed interface circuit that is mounted on a load board interfacing with an LSI tester, is provided with a circuit converting the signal speed, and is capable of changing the transmission and reception characteristics; a controller that controls the transmission and reception characteristics of the high-speed interface circuit; a clock generator that generates the clock supplied to the high-speed interface circuit; a first connector provided specifically for the high-speed interface, connected to the high-speed interface circuit and provided with a signal port for performing high-speed signal communication with a circuit under test; and a second connector connected to the high-speed interface circuit and the LSI tester and provided with a signal port and a power port for performing low-speed signal communication with the high-speed interface circuit.

### BACKGROUND OF THE INVENTION

1. Field of the Invention

The present invention relates to a high-speed interface circuit test module being a test module for an LSI provided with a high-speed interface circuit, a module under high-speed interface circuit test, and a high-speed interface circuit test method.

2. Description of the Prior Art

Conventionally, a test of an LSI provided with a high-speed interface circuit such as IEEE 1394 or Serial ATA has been realized by use of a high-speed LSI tester capable of inputting and outputting high-speed signals (for example, see Non-patent Document 1). Moreover, there is a method that realizes the test without the use of a high-speed LSI tester by providing a high-speed interface circuit on a DUT (device under test) board (also called load board) (for example, see Hiroshi Kaga, “LSI tesuto kuraisisu no “keikou to taisaku” (“Tendency and Countermeasure” of LSI Test Crisis)”, Design Wave Magazine 2004 February, and Japanese Laid-Open Patent Application No. 2000-285036).

In the former case using a high-speed LSI tester, the test is realized by directly inputting and outputting a high-speed signal to and from the LSI under test. In this case, not only a functional test based on a real speed but also a test of communication characteristics is realized by changing the amplitude of the signal outputted from the high-speed LSI tester, the capture threshold value voltage level at the time of input, and further, the timing of the input and output signals and the like.

In the latter case in which a high-speed interface circuit is provided on a DUT board, the test is realized by inputting and outputting a high-speed signal to and from the LSI under test (synonymous with DUT) through the high-speed interface circuit on the DUT board by use of a low-speed LSI tester. In this case, since the amplitude of the signal outputted from the high-speed interface circuit on the DUT board, the capture threshold value voltage level at the time of input, and further, the timing and the jitter amount are fixed, only a functional test based on a real speed is realized.

Moreover, in both of the former and latter cases, since a high-speed transmission line on the periphery of the LSI under test is constructed on the DUT board, it is necessary to debug the high-speed transmission line on the DUT board by use of the LSI tester.

However, according to the above-described prior art, in the former case, a high-speed LSI tester is required. High-speed LSI testers are generally more expensive than low-speed LSI testers. Consequently, the cost of the test is increased. In the latter case, although the increase in the cost of the test can be suppressed, since the characteristic test of the high-speed interface circuit cannot be performed, there is a possibility that the guarantee of the characteristics is insufficient, so that there is a possibility that defectives flow out.

Moreover, generally, it is impossible to possess, for boards and test program debugging, a multiplicity of LSI testers which are expensive equipment. Therefore, it is extremely inefficient to use an LSI tester for debugging of the high-speed transmission line on the DUT board.

### SUMMARY OF THE INVENTION

The present invention is made in view of the above-mentioned problem, and an object thereof is to provide a high-speed interface circuit test module, a module under high-speed interface circuit inspection and a high-speed interface circuit test method capable of guaranteeing the communication characteristics at low test cost and efficiently performing the debugging of the high-speed transmission line on the board by solving the problem that in the shipment test of LSIs provided with a high-speed interface circuit, it is impossible to realize both cost reduction and a high test guarantee level because the test is realized by using a high-speed LSI tester that leads to an increase in test cost or providing a high-speed interface circuit having fixed transmission and reception characteristics on the DUT board.

To solve the above-mentioned problem, a high-speed interface circuit test module according to a first and second aspect of the invention is provided with: a high-speed interface circuit that is provided with a circuit converting a signal speed, and is capable of changing transmission and reception characteristics; a controller that controls the transmission and reception characteristics of the high-speed interface circuit; a clock generator that generates a clock supplied to the high-speed interface circuit; a first connector provided specifically for a high-speed interface, connected to the high-speed interface circuit and provided with a signal port for performing high-speed signal communication with a circuit under test; and a second connector connected to the high-speed interface circuit and the LSI tester and provided with a signal port and a power port for performing low-speed signal communication with the high-speed interface circuit. Moreover, the high-speed interface circuit is provided with a test algorithm serving as a procedure by which the high-speed interface is tested.

According to this structure, a high-speed interface circuit test module is mounted on a DUT board (load board) and the high-speed signal is inputted and outputted to and from an LSI under test through the high-speed interface circuit test module by use of a low-speed LSI tester, thereby realizing a high-speed interface circuit test. In this case, since the high-speed interface circuit test module whose transmission and reception characteristics are changeable is capable of changing the amplitude of the output signal, the capture threshold value voltage level at the time of input and further, the input and output signal timing and the like, not only a functional test based on a real speed but also a test of communication characteristics can be realized.

As described above, since the function of the high-speed interface and the communication characteristic test can be realized without the use of the high-speed LSI tester, the test cost can be prevented from increasing while a high test guarantee level is maintained.

In a high-speed interface circuit test module according to a third aspect of the invention, a signal port for setting the transmission and reception characteristics of the high-speed interface circuit is provided in the second connector in the high-speed interface circuit test module according to the first or second aspect of the invention.

According to this structure, the transmission and reception characteristics of the driver and the receiver of the high-speed interface circuit can be arbitrarily changed.

In a high-speed interface circuit test module according to a fourth aspect of the invention, a fixed switch for setting the transmission and reception characteristics of the high-speed interface circuit is provided in the high-speed interface circuit test module according to the first or second aspect of the invention.

According to this structure, the transmission and reception characteristics of the driver and the receiver of the high-speed interface circuit can be arbitrarily changed.

In a high-speed interface circuit test module according to a fifth aspect of the invention, a serial or parallel interface circuit having a general-purpose communication protocol for performing the low-speed signal communication and change setting of the transmission and reception characteristics is provided in the high-speed interface circuit test module according to the first, second, third or fourth aspect of the invention.

According to this structure, the transmission and reception characteristics of the driver and the receiver of the high-speed interface circuit can be arbitrarily changed. Moreover, versatility increases with respect to the control means from the outside of the high-speed interface circuit.

In a high-speed interface circuit test module according to a sixth aspect of the invention, instead of the clock generator, a clock supply port is provided in the second connector in the high-speed interface circuit test module according to the first, second, third or fourth aspect of the invention.

According to this structure, a clock signal can be supplied from the LSI tester.

In a high-speed interface circuit test module according to a seventh aspect of the invention, both or either of a high-speed interface test pattern generator that inputs a pattern to the high-speed interface circuit and a pattern comparator that compares an output from the high-speed interface circuit with an expected value is provided in the high-speed interface circuit test module according to the first, second, third or fourth aspect of the invention.

According to this structure, by performing the test with the pattern generator and the pattern comparator being provided in the high-speed interface circuit test module, it is unnecessary for the LSI tester to use tester functions such as the matching function and the digital capture function of the LSI tester necessary for obtaining synchronism with the input and output of the low-speed signal of the LSI under test and the reference LSI of the high-speed interface circuit test module, so that the creation of the test program and the test pattern of the LSI tester is facilitated.

In a high-speed interface circuit test module according to an eighth aspect of the invention, a modulator that modulates the clock supplied to the high-speed interface circuit or a jitter injector that injects jitter to change a clock characteristic is provided in the high-speed interface circuit test module according to the first or second aspect of the invention.

According to this structure, since the clock characteristic can be arbitrarily set from the outside by the frequency modulator or the jitter injector, a difficult condition for the LSI under test to perform the transmission or reception of the high-speed signal can be created.

In a high-speed interface circuit test module according to a ninth aspect of the invention, a signal port for setting the clock characteristic based on the modulation amount and the modulation frequency of the modulator or the jitter amount of the jitter injector is provided in the second connector in the high-speed interface circuit test module according to the eighth aspect of the invention.

According to this structure, by changing the characteristic values of the modulation frequency and the modulation amount of the frequency modulator and the jitter amount of the jitter injector from the LSI tester, the characteristic evaluation of the high-speed transmission and reception tests can be performed under various conditions.

In a high-speed interface circuit test module according to a tenth aspect of the invention, a fixed switch for setting the clock characteristic based on the modulation amount and the modulation frequency setting of the modulator or the jitter amount of the jitter injector is provided in the high-speed interface circuit test module according to the eighth aspect of the invention.

According to this structure, by changing the characteristic values of the modulation frequency and the modulation amount of the frequency modulator and the jitter amount of the jitter injector by controlling the fixed switch on the high-speed interface circuit test module, the characteristic evaluation of the high-speed transmission and reception tests can be performed under various conditions. Moreover, the control signal from the LSI tester is unnecessary, so that the test time can be reduced although the reduction amount is slight.

In a high-speed interface circuit test module according to an eleventh aspect of the invention, a plurality of connectors similar to the first connector provided specifically for the high-speed interface and a relay that switches connection between the high-speed interface circuit and the connectors are provided, and a control signal port for switching the relay is provided in the second connector in the high-speed interface circuit test module according to the first, second, third or fourth aspect of the invention.

According to this structure, since a plurality of high-speed signal transmission conditions can be set by arbitrarily switching, from the outside, among a plurality of kinds of high-speed-interface-specific cables being provided, a difficult condition for the LSI under test to perform the transmission or reception of the high-speed signal can be created.

In a high-speed interface circuit test module according to a twelfth aspect of the invention, a relay that switches an object to which a high-speed terminal of the high-speed interface circuit connected to the first connector is connected is provided, and an input and output signal port of the high-speed terminal and a control signal port for switching the relay are provided in the second connector in the high-speed interface circuit test module according to the first, second, third or fourth aspect of the invention.

According to this structure, by testing the high-speed terminal of the high-speed interface circuit before performing the high-speed transmission and reception tests, the change amount is set with respect to a reference value by using as the reference value the measurement result of the driver circuit and the receiver circuit of the high-speed terminal, and the change of desired transmission characteristics and reception characteristics for performing the high-speed signal transmission and reception tests can be set.

In a high-speed interface circuit test module according to a thirteenth aspect of the invention, a filter or jitter injector that changes the high-speed signal transmission characteristic is provided between the high-speed interface circuit and the first connector in the high-speed interface circuit test module according to the first or second aspect of the invention.

According to this structure, since the high-speed signal transmission characteristic can be arbitrarily set from the outside by the filter or jitter injector disposed on the high-speed signal transmission line, a difficult condition for the LSI under test to perform the transmission or reception of the high-speed signal can be created.

In a high-speed interface circuit test module according to a fourteenth aspect of the invention, a signal port for setting the high-speed signal transmission characteristic is provided in the second connector in the high-speed interface circuit test module according to the thirteenth aspect of the invention.

According to this structure, by changing the characteristic value of the filter or jitter injector from the LSI tester, the characteristic evaluation of the high-speed transmission and reception tests can be performed under various conditions.

In a high-speed interface circuit test module according to a fifteenth aspect of the invention, a fixed switch for setting the high-speed signal transmission characteristic is provided in the high-speed interface circuit test module according to the thirteenth aspect of the invention.

According to this structure, by changing the characteristic value of the filter or jitter injector by controlling the fixed switch on the high-speed interface circuit test module, the characteristic evaluation of the high-speed transmission and reception tests can be performed under various conditions. Moreover, the control signal from the LSI tester is unnecessary, so that the test time can be reduced although the reduction amount is slight.

A module under high-speed interface circuit test according to a sixteenth aspect of the invention is provided with: a circuit under test being independent of the high-speed interface circuit test module according to the first or second aspect of the invention and including a high-speed interface circuit under test; a clock generator that generates a clock supplied to the circuit under test; a third connector provided specifically for a high-speed interface, connected to the circuit under test and provided with a signal port for performing high-speed signal communication with the high-speed interface circuit test module; and a fourth connector provided with a signal port and a power port connected to all terminals or a given terminal of the circuit under test.

According to this structure, the module under high-speed interface circuit test can be made disconnectable from the load board by the fourth connector for low-speed signal communication. In this case, the high-speed interface circuit test module and the peripheral board of the LSI under test are disconnectable from the DUT board (load board) because they interface with the DUT board by the second connector and the fourth connector, and the high-speed transmission line is absent on the DUT board. Since the first connector and the third connector can be connected by the high-speed-interface-specific cable, the high-speed interface circuit test module and the peripheral board of the LSI under test can be debugged without the use of the LSI tester, so that the development period can be reduced.

In a module under high-speed interface circuit test according to a seventeenth aspect of the invention, a relay that switches an object to which a high-speed terminal of the circuit under test connected to the third connector is connected is provided, and an input and output signal port of the high-speed terminal of the circuit under test and a control signal port for switching the relay are provided in the fourth connector in the module under high-speed interface circuit test according to the sixteenth aspect of the invention.

According to this structure, since the object to which the high-speed terminal of the LSI under test is connected can be switched to the fourth connector for low-speed signal communication, the DC test on the high-speed terminal and the test by the low-speed signal can be performed by the LSI tester.

In a high-speed interface circuit test module according to an eighteenth aspect of the invention, a conductive metal terminal for electric signal input and output is used instead of the first and second connectors in the high-speed interface circuit test module according to the first, second, third or fourth aspect of the invention.

According to this structure, connection is made by the metal wire.

In a module under high-speed interface circuit test according to a nineteenth aspect of the invention, a conductive metal terminal for electric signal input and output is used instead of the third and fourth connectors in the module under high-speed interface circuit test according to the sixteenth or seventeenth aspect of the invention.

According to this structure, connection is made by the metal wire.

A high-speed interface circuit test method according to a twentieth aspect of the invention is provided with: a step where transmission and reception characteristics, a clock characteristic and a high-speed signal transmission characteristic are set to given values from an LSI tester to the high-speed interface circuit test module according to the first or second aspect of the invention; a step where input and output of a test low-speed signal and a control signal, and application of power are performed between the high-speed interface circuit test module and the LSI tester; a step where input and output of a test high-speed signal obtained by converting transmission data by the test low-speed signal into a high-speed signal is performed between an LSI under test and the high-speed interface circuit test module; and a step where the LSI tester compares reception data obtained by converting the test high-speed signal into a low-speed signal with an expected value, and determines a test result.

According to this structure, the test can be performed by use of the high-speed interface circuit test module. Consequently, by arbitrarily setting the transmission and reception characteristics of the driver, the receiver and the like of the high-speed interface circuit which is the object of the transmission and reception of the LSI under test in the transmission and reception tests of the high-speed interface circuit that interfaces at high speed, a difficult condition for the LSI under test to perform the transmission or reception of the high-speed signal can be created. Further, since the test can be realized by the interface of only the low-speed signal with the LSI tester, the mass production test of the high-speed interface can be realized only by an inexpensive LSI tester that interfaces at low speed and the high-speed interface circuit test module of the simple structure disposed on the load board, so that the test cost can be prevented from increasing.

In the high-speed interface circuit test method according to a twenty-first aspect of the invention, a digital signal input and output device capable of generating and capturing a digital signal and applying power is used instead of the LSI tester in the high-speed interface circuit test method according to the twentieth aspect of the invention.

According to this structure, the LSI under test can be evaluated by using a DC measuring instrument, an oscilloscope, a digitizer or the like.

In the high-speed interface circuit test method according to a twenty-second aspect of the invention, a test is performed by use of the LSI under test or a loopback test circuit of the high-speed interface circuit test module in the high-speed interface circuit test method according to the twentieth or twenty-first aspect of the invention.

According to this structure, since the transmission test and the reception test can be performed at a time, the test time can be reduced.

In the high-speed interface circuit test method according to a twenty-third aspect of the invention, the test low-speed signal is generated in the high-speed interface circuit test module or the comparison with the expected value is performed in the high-speed interface circuit test method according to the twentieth aspect of the invention.

According to this structure, since it is unnecessary for the LSI tester to use tester functions such as the matching function and the digital capture function of the LSI tester necessary for obtaining synchronism with the input and output of the low-speed signal of the LSI under test and the reference LSI of the high-speed interface circuit test module, the creation of the test program and the test pattern of the LSI tester is facilitated.

In the high-speed interface circuit test method according to a twenty-fourth aspect of the invention, all the test low-speed signals and the expected value are previously inputted from the LSI tester before a test, and the test is performed while a necessary signal is switched every test in the high-speed interface circuit test method according to the twenty-third aspect of the invention.

According to this structure, since the transmission test can be performed by use of a plurality of kinds of transmission data, a plurality of kinds of difficult conditions for the LSI under test to perform the transmission or reception of the high-speed signal can be created.

In the high-speed interface circuit test method according to a twenty-fifth aspect of the invention, the LSI under test and the high-speed interface circuit test module are connected by a plurality of kinds of different cables, and a necessary cable is selected at the time of a test by relay switching control from the LSI tester in the high-speed interface circuit test method according to the twentieth or twenty-first aspect of the invention.

According to this structure, since a plurality of high-speed signal transmission conditions can be set by arbitrarily switching, from the outside, among a plurality of kinds of high-speed-interface-specific cables being provided, a difficult condition for the LSI under test to perform the transmission or reception of the high-speed signal can be created.

In the high-speed interface circuit test method according to a twenty-sixth aspect of the invention, a transmission and reception circuit characteristic of the high-speed interface circuit in the high-speed interface circuit test module is tested at the LSI tester, and transmission and reception characteristics are determined based on a result of the test in the high-speed interface circuit test method according to the twentieth aspect of the invention.

According to this structure, by testing the high-speed terminal of the high-speed interface circuit by the LSI tester before performing the high-speed transmission and reception tests, the change amount is set with respect to a reference value by using as the reference value the measurement result of the driver circuit and the receiver circuit of the high-speed terminal, and the change of desired transmission characteristics and reception characteristics for performing the high-speed signal transmission and reception tests can be set.

In the high-speed interface circuit test method according to a twenty-seventh aspect of the invention, a transmission and reception circuit characteristic of the high-speed interface circuit in the high-speed interface circuit test module is tested at the LSI tester, and whether to continue or cancel the test is determined based on a result of the test in the high-speed interface circuit test method according to the twenty-sixth aspect of the invention.

According to this structure, since the high-speed terminal of the reference LSI of the high-speed interface circuit are tested by the LSI tester before performing the high-speed transmission and reception tests and a quality determination as to whether the high-speed interface circuit of the reference LSI is out of order or not can be made based on the result, it can be determined that the execution of the high-speed signal transmission and reception tests is canceled or that the reference LSI is changed to another chip, so that the test quality and maintainability can be ensured.

### BRIEF DESCRIPTION OF THE DRAWINGS

FIG. 1 is a view showing the structure of a high-speed interface circuit test module of a first embodiment of the present invention;

FIG. 2 is a flowchart showing a test method using the high-speed interface circuit test module of the embodiment of the present invention;

FIG. 3 is a flowchart showing another test method using the high-speed interface circuit test module of the embodiment of the present invention;

FIG. 4 is a flowchart showing another test method using the high-speed interface circuit test module of the embodiment of the present invention;

FIG. 5 is a flowchart showing another test method using the high-speed interface circuit test module of the embodiment of the present invention;

FIG. 6 is a view showing the structure of a high-speed interface circuit test module of a second embodiment of the present invention;

FIG. 7 is a view showing the structure of a high-speed interface circuit test module of a third embodiment of the present invention;

FIG. 8 is a view showing the structure of a high-speed interface circuit test module of a fourth embodiment of the present invention;

FIG. 9 is a view showing the structure of a high-speed interface circuit test module of a fifth embodiment of the present invention;

FIG. 10 is a view showing the structure of a high-speed interface circuit test module of a sixth embodiment of the present invention;

FIG. 11 is a view showing the structure of a high-speed interface circuit test module of a seventh embodiment of the present invention;

FIG. 12 is a flowchart showing another test method using the high-speed interface circuit test module of the seventh embodiment of the present invention; and

FIG. 13 is a flowchart showing another test method using the high-speed interface circuit test module of the seventh embodiment of the present invention.

### DESCRIPTION OF PREFERRED EMBODIMENTS

Hereinafter, embodiments of the present invention will be described with reference to the drawings.

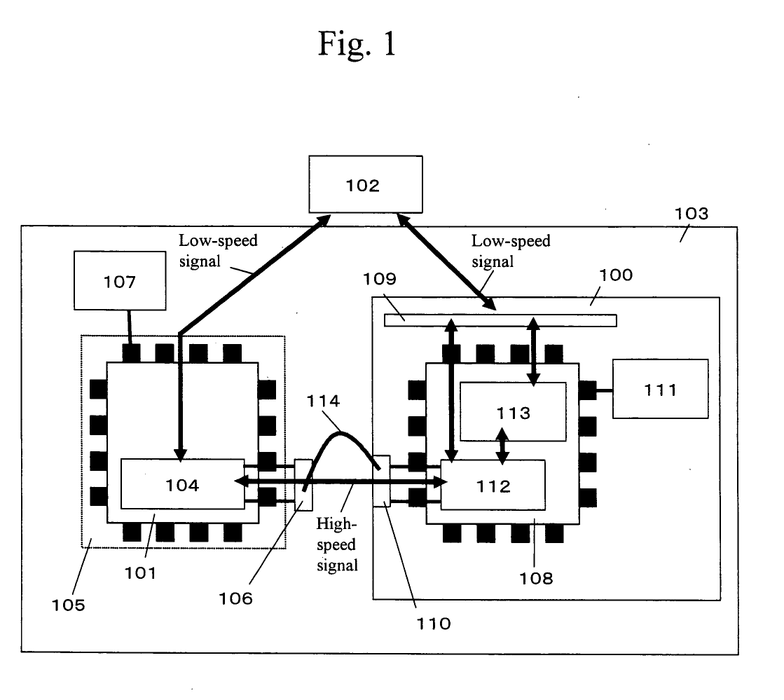

A first embodiment of the present invention will be described with reference to FIGS. 1 to 5. As the first embodiment, an embodiment according to claims 1, 2, 3, 4, 5 and 6 and claims 20 and 22 will be described. FIG. 1 shows the structure of an LSI test using a high-speed interface circuit test module 100 according to the first embodiment of the present invention.

In a test process constituted by an LSI tester 102, an LSI under test 101 and a load board (test board) 103 serving as the interface of the connection between the LSI tester 102 and the LSI under test 101, the high-speed interface circuit test module 100 of the embodiment of the present invention is used being disposed on the load board 103.

The LSI under test 101 is provided with a high-speed interface circuit 104 having circuits such as a driver circuit and a receiver circuit for the high-speed signal interfacing with the outside of the LSI at high speed and a serializer and a deserializer that convert the signal speed between the high-speed signal and the low-speed signal. The LSI under test 101 is connected to the load board 103 through an LSI socket 105 disposed on the load board 103. A signal pin and a power pin that are necessary for the access to the low-speed signal inputted and outputted to and from the high-speed interface circuit 104 are connected to the LSI tester 102 and the LSI under test 101. The high-speed signal input and output terminals of the LSI under test 101 are connected through pattern wiring to a third connector 106 provided specifically for the high-speed interface disposed on the load board 103 to transmit the high-speed signal to the outside. To supply a clock signal to the LSI under test 101, a clock generator 107 is disposed on the load board 103 and connected to the clock input terminal of the LSI under test 101. Instead of providing the clock generator 107, the clock signal may be supplied from the LSI tester 102.

The high-speed interface circuit test module 100 is provided with: a reference LSI 108 disposed on the load board 103 and interfacing with the outside of the LSI at high speed; a second connector 109 for low-speed signal communication connected to the load board 103 and performing the transmission and reception of the low-speed signal with the LSI tester 102; a first connector 110 provided specifically for the high-speed interface for transmitting the high-speed signal to the outside; and a clock generator 111 that generates a clock supplied to the reference LSI 108. The reference LSI 108 is provided with: a high-speed interface circuit 112 having circuits such as a driver circuit and a receiver circuit for the high-speed signal interfacing with the outside at high speed and whose transmission and reception characteristics can be arbitrarily changed from the outside and a serializer and a deserializer that convert the signal speed between the high-speed signal and the low-speed signal; and a characteristic control register circuit (controller) 113 for arbitrarily changing the transmission and reception characteristics of the driver and the receiver of the high-speed interface circuit 112 from the outside. It is necessary to previously confirm that the reference LSI 108 is a conforming item by a high-speed LSI tester, a high-frequency measuring instrument or the like capable of measuring characteristics of the high-speed interface. The second connector 109 for low-speed signal communication is provided with a signal port and a power port connecting the load board 103 and the high-speed interface circuit test module 100 and required for the access by the low-speed signal of the LSI tester 102 and the high-speed interface circuit 112. With respect to the setting of the transmission and reception characteristics to the characteristic control register circuit 113, the transmission and reception characteristics may be set by providing a signal port in the second connector 109 for low-speed signal communication (the structure according to claim 3), the transmission and reception characteristics may be set by providing a fixed switching circuit on the high-speed interface circuit test module 100 (the structure according to claim 4), or the transmission and reception characteristic setting of the initial condition of the characteristic control register circuit 113 that is set when the power is turned on may be used without any external control. In addition to the method that directly controls the high-speed interface circuit 112 and the characteristic control register circuit 113 from the LSI tester 102, a serial or parallel communication protocol interface circuit having a general-purpose communication protocol and performing the low-speed signal communication and the processing of change setting of the transmission and reception characteristics to control the operations of the high-speed interface circuit 112 and the characteristic control register circuit 113 may be provided on the high-speed interface circuit test module 100 and connected to both of the LSI tester 102 and the reference LSI 108 (the structure according to claim 5). By these structures, the transmission and reception characteristics of the driver and the receiver of the high-speed interface circuit 112 can be arbitrarily changed by the input of a signal from the LSI tester 102, the fixed switching circuit or the communication protocol interface circuit. Moreover, the first connector 110 provided specifically for the high-speed interface is connected to the high-speed signal input and output terminals of the reference LSI 108 through pattern wiring. The first connector 110 provided specifically for the high-speed interface and the third connector 106 provided specifically for the high-speed interface and situated in the vicinity of the LSI under test 101 are connected together by a high-speed-interface-specific cable 114. This connects the high-speed signal input and output terminals of the LSI under test 101 and the high-speed signal input and output terminals of the reference LSI 108 together. The clock generator 111 is connected to the clock input terminal of the reference LSI 108 to supply the clock signal. Instead of providing the clock generator 111, the clock signal may be supplied from the LSI tester 102 by providing a clock supply port in the second connector 109 for low-speed signal communication (the structure according to claim 6).

The power supply to the devices is performed from the LSI tester 102 (the above-described is the structure according to claims 1 and 2).

Next, an LSI test method using the high-speed interface circuit test module 100 of the embodiment of the present embodiment will be described.

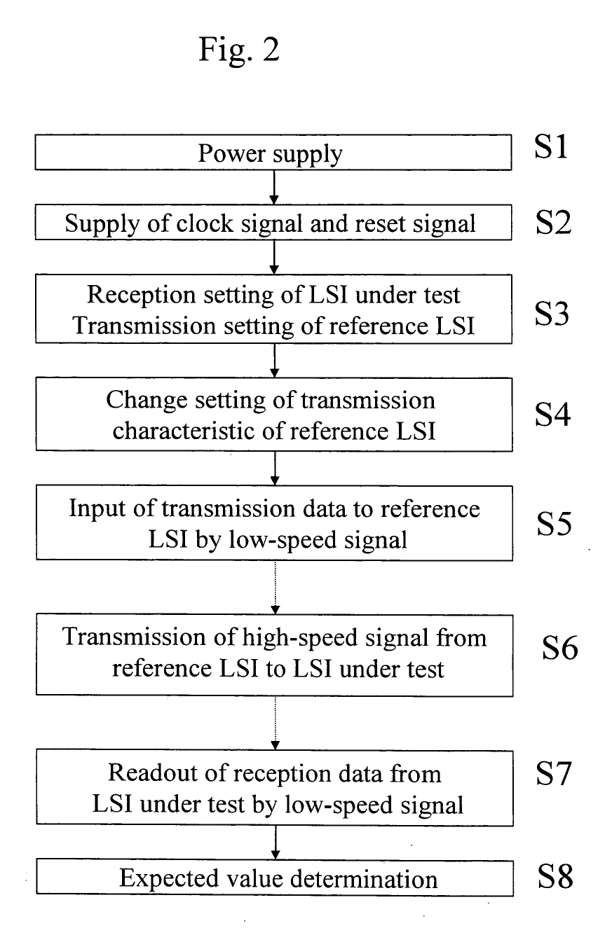

First, a reception test of the high-speed interface circuit 104 of the LSI under test 101 will be described. FIG. 2 is the control flow of the test according to the first embodiment of the present invention.

A predetermined test voltage is supplied from the LSI tester 102 to the power terminals and the input terminals of the LSI under test 101 and the reference LSI 108 (S1), and a reset signal is supplied. Moreover, the clock signal is supplied to the LSI under test 101 and the reference LSI 108 by the clock generator 107 and the clock generator 111 (S2). The clock signal may be supplied from the LSI tester 102 by way of the load board 103 and the second connector 109 for low-speed signal communication (the method by the structure according to claim 6). Then, the high-speed interface circuit 104 of the LSI under test 101 and the high-speed interface circuit 112 of the reference LSI 108 on the high-speed interface circuit test module 100 are accessed from the LSI tester 102 by the low-speed signal, and the reception setting and the transmission setting are made thereon (S3). Moreover, for the characteristic control register circuit 113, a desired register setting is made on the characteristic control register circuit 113 by the input of the control signal from the LSI tester 102 (the method by the structure according to claim 3), by the input of the control signal by the fixed switching circuit (the method by the structure according to claim 4), or by use of the set values of the transmission and reception characteristics of the initial condition of the characteristic control register circuit 113 without any external control, whereby the transmission characteristic of the driver circuit of the high-speed interface circuit 112 is set so as to be changed (S4) For example, the amplitude of the voltage which is the output signal from the driver is increased or decreased by changing the output current amount of the driver circuit, or the following setting is made: the setting to shift the common mode level intermediate between the high level and the low level from the ideal potential; or the setting where the transmitting end resistance of the driver is variable and signal reflection readily occurs due to an impedance mismatch. This enables the creation of a condition under which it is difficult for the receiver circuit of the high-speed interface circuit 104 of the LSI under test 101 to receive the high-speed signal. The transmission setting of the high-speed interface circuit 112 and the transmission characteristic setting to the characteristic control register circuit 113 may be controlled by use of the communication protocol interface circuit (the method by the structure according to claim 5).

Then, a test pattern of the low-speed signal for data transmission is inputted from the LSI tester 102 to the reference LSI 108 (S5). The test pattern for data transmission is converted into the high-speed signal by serializing or the like at the high-speed interface circuit 112 of the reference LSI 108, and the high-speed signal is transmitted from the driver circuit (S6). The high-speed signal passes through the first connector 110 provided specifically for the high-speed interface, the high-speed-interface-specific cable 114 and the third connector 106 provided specifically for the high-speed interface to be inputted to the input terminal of the LSI under test 101. That is, the receiver circuit of the high-speed interface circuit 104 of the LSI under test 101 receives the data of the high-speed signal. The received high-speed signal is converted into the low-speed signal by deserializing or the like at the high-speed interface circuit 104. The LSI tester 102 reads out the reception data converted into the low-speed signal of the high-speed interface circuit 104 (S7). It is necessary for the LSI tester 102 to capture data into the memory of the LSI tester 102 in synchronism with the output timing of the reception data of the LSI under test 101, and as an example, the synchronism is obtained by use of the function of matching the output data with the expected value and the function of capturing digital data into the memory in a predetermined cycle which are functions of the LSI tester. When a FIFO circuit is present within the LSI under test 101, synchronism with the LSI tester is obtained by converting the output timing of the reception data inputted to the FIFO circuit so that the reception data is in synchronism with the external clock, that is, the clock of the LSI tester 102. Lastly, the reception data is compared with the expected value by the LSI tester 102, and it is determined whether the reception test of the LSI under test 101 is good or not (S8).

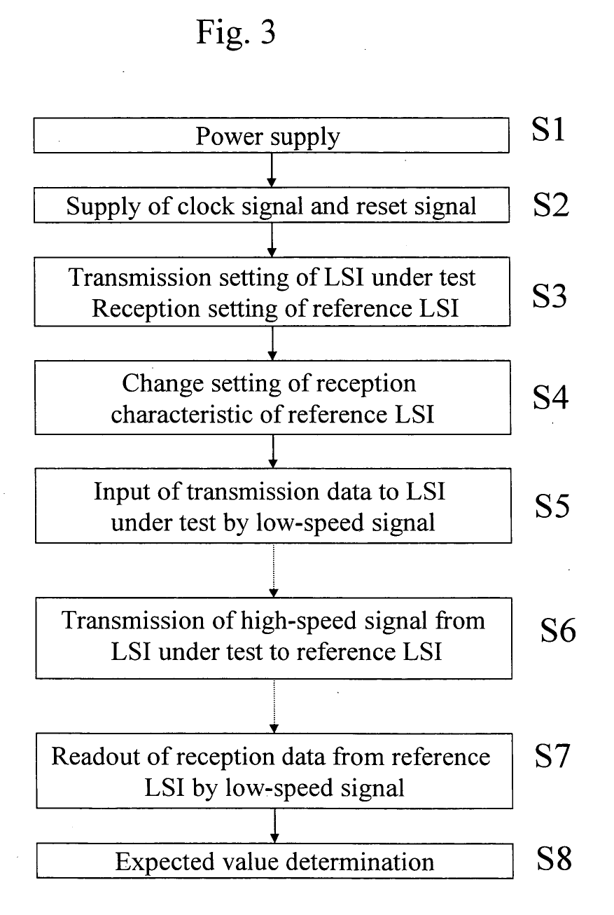

Next, a transmission test of the high-speed interface circuit 104 of the LSI under test 101 will be described. FIG. 3 is the control flow of another test according to the first embodiment of the present invention.

A predetermined test voltage is supplied from the LSI tester 102 to the power terminals and the input terminals of the LSI under test 101 and the reference LSI 108 (S1), and a reset signal is supplied. Moreover, a clock signal is supplied to the LSI under test 101 and the reference LSI 108 by the clock generator 107 and the reference LSI 108 (S2). The clock signal may be supplied from the LSI tester 102 by way of the second connector 109 for low-speed signal communication (the method by the structure according to claim 6). Then, the high-speed interface circuit 104 of the LSI under test 101 and the high-speed interface circuit 112 of the reference LSI 108 on the high-speed interface circuit test module 100 are accessed from the LSI tester 102 by the low-speed signal, and the transmission setting and the reception setting are made thereon (S3). Moreover, for the characteristic control register circuit 113, a desired register setting is made on the characteristic control register circuit 113 by the input of the control signal from the LSI tester 102 (the method by the structure according to claim 3), by the input of the control signal by the fixed switching circuit (the method by the structure according to claim 4), or by use of the set values of the transmission and reception characteristics of the initial condition without any external control, whereby the reception characteristic of the driver circuit of the high-speed interface circuit 112 is set so as to be changed (S4). For example, the following setting is made: the setting to decrease the amplitude of the voltage that can be received by the receiver by changing the detection current value and the detection reference voltage value of the receiver circuit; the setting to shift the common mode voltage intermediate between the high level and the low level from the ideal potential by changing the amount of pull-in current of the receiver circuit; or the setting where the terminating resistance of the receiver is variable and signal reflection readily occurs due to an impedance mismatch. This enables the creation of a condition under which it is difficult for the driver circuit of the high-speed interface circuit 104 of the LSI under test 101 to transmit the high-speed signal. The reception setting of the high-speed interface circuit 112 and the reception characteristic setting to the characteristic control register circuit 113 may be controlled by use of the communication protocol interface circuit (the method by the structure according to claim 5).

Then, a test pattern of the low-speed signal for data transmission is inputted from the LSI tester 102 to the LSI under test 101 (S5). The test pattern for data transmission is converted into the high-speed signal by serializing or the like at the high-speed interface circuit 104 of the LSI under test 101, and the high-speed signal is transmitted from the driver circuit (S6). The high-speed signal passes through the third connector 106 provided specifically for the high-speed interface, the high-speed-interface-specific cable 114 and the first connector 110 provided specifically for the high-speed interface to be inputted to the input terminal of the reference LSI 108. That is, the receiver circuit of the high-speed interface circuit 112 of the reference LSI 108 receives the data of the high-speed signal. The received high-speed signal is converted into the low-speed signal by deserializing or the like at the high-speed interface circuit 112. The LSI tester 102 reads out the reception data converted into the low-speed signal of the high-speed interface circuit 112 (S7). The data is captured into the memory of the LSI tester 102 in synchronism with the output timing of the reception data of the high-speed interface circuit 112, for example, by the reception data capturing method by the above-mentioned functions of the LSI tester 102. Lastly, the reception data is compared with the expected value by the LSI tester 102, and it is determined whether the transmission test of the LSI under test 101 is good or not (S8) (the above-described is the method according to claim 20).

While the reception test and the transmission test of the LSI under test 101 are separately described, when a loopback function is provided within the LSI under test 101, that is, when the function of transmitting the data received by the receiver circuit to the driver circuit as it is through deserializing and serializing is provided, the reception test and the transmission test may be performed at a time.

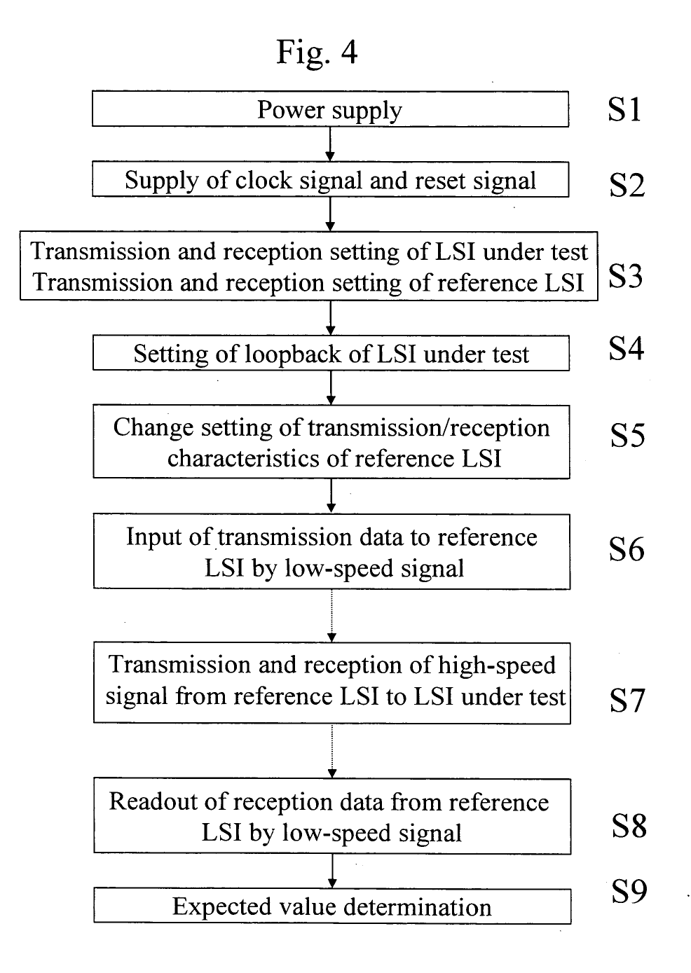

FIG. 4 is the control flow of a test according to a modification of the first embodiment of the present invention. A predetermined test voltage is supplied from the LSI tester 102 to the power terminals and the input terminals of the LSI under test 101 and the reference LSI 108 (S1), and a reset signal is supplied. Moreover, the clock signal is supplied to the LSI under test 101 and the reference LSI 108 by the LSI tester 102 or the clock generator 107 and the clock generator 111 (S2). Then, the high-speed interface circuit 104 of the LSI under test 101 and the high-speed interface circuit 112 of the reference LSI 108 on the high-speed interface circuit test module 100 are accessed from the LSI tester 102 by the low-speed signal, and the transmission and reception setting is made thereon (S3). Further, the setting to perform a loopback operation is made on the LSI under test 101 (S4). The test pattern is converted into the high-speed signal by serializing or the like at the high-speed interface circuit 112, and the high-speed signal is transmitted from the driver circuit.

By setting the transmission characteristic of the driver circuit of the high-speed interface circuit 112 so as to be changed by making a desired register setting on the characteristic control register circuit 113 (S5), a condition under which it is difficult for the receiver circuit of the high-speed interface circuit 104 of the LSI under test 101 to receive the high-speed signal is created. A test pattern of the low-speed signal for data transmission is inputted from the LSI tester 102 to the reference LSI 108 (S6). The high-speed signal passes through the first connector 110 provided specifically for the high-speed interface, the high-speed-interface-specific cable 114 and the third connector 106 provided specifically for the high-speed interface to be inputted to the input terminal of the LSI under test 101. That is, the receiver circuit of the high-speed interface circuit 104 of the LSI under test 101 receives the data of the high-speed signal. At the high-speed interface circuit 104, after the received high-speed signal is converted into the low-speed signal by deserializing or the like, the converted low-speed data is converted into the high-speed signal by a serializer or the like by way of the path of a loopback for transfer to the driver side, and the converted high-speed signal is transmitted from the driver circuit to the reference LSI 108 (S7). By setting the reception characteristic of the receiver circuit of the high-speed interface circuit 112 so as to be changed by making a desired register setting on the characteristic control register circuit 113 (S5), a condition under which it is difficult for the receiver circuit of the high-speed interface circuit 104 of the LSI under test 101 to receive the high-speed signal is created. By this method, the reception data of the reference LSI 108 that is received finally is converted into the low-speed signal, read out by the LSI tester 102 (S8), and compared with the expected value. Then, it is determined whether the reception and transmission tests of the LSI under test 101 are good or not (S9).

Moreover, the transmission and reception tests of the LSI under test 101 may be performed with a data flow diametrically opposite to the above-described one by providing a circuit of the loopback function within the reference LSI 108.

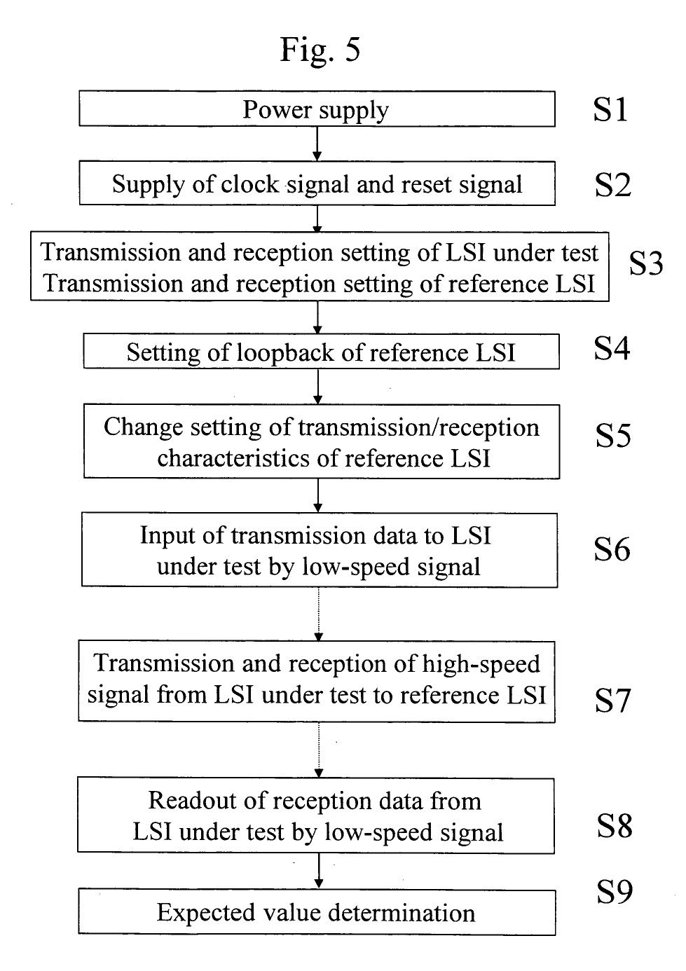

FIG. 5 is the control flow of a test according to a modification of the first embodiment of the present invention. The setting to perform a loopback operation is made on the reference LSI 108 (S4). Then, a test pattern of the low-speed signal for data transmission is inputted from the LSI tester 102 to the LSI under test 101 (S6). The LSI under test 101 converts the test pattern into the high-speed signal by serializing or the like and transmits the data. The high-speed signal passes through the third connector 106 provided specifically for the high-speed interface, the high-speed-interface-specific cable 114 and the first connector 110 provided specifically for the high-speed interface to be inputted to the input terminal of the reference LSI 108. The reference LSI transfers the high-speed data to the LSI under test 101 by way of the path of the loopback, and transmits the high-speed signal (S7). After the LSI under test 101 converts the received high-speed signal into a low-speed signal by deserializing or the like, the low-speed signal is readout by the LSI tester 102 (S8) and compared with the expected value. Then, it is determined whether the transmission and reception tests of the LSI under test 101 are good or not (S9) (the above-described is the method according to claim 22).

As described above, by performing the test by use of the high-speed interface circuit test module 100 like the structures according to claims 1 and 2 of the present invention and the method according to claim 19, in the transmission and reception tests of the high-speed interface circuit 104 that interfaces by the high-speed signal, by arbitrarily setting the transmission and reception characteristics of the driver, the receiver and the like of the high-speed interface circuit 112 of the reference LSI 108 which is the object of the transmission and reception of the LSI under test 101, a difficult condition for the LSI under test 101 to perform the transmission or reception of the high-speed signal can be created. Further, since the test can be realized by the interface of only the low-speed signal with the LSI tester 102, the mass production test of the high-speed interface can be realized only by an inexpensive LSI tester that interfaces at low speed and the high-speed interface circuit test module 100 of the simple structure disposed on the load board 103, so that the test cost can be prevented from increasing.

Moreover, by changing the transmission and reception characteristics of the high-speed interface circuit 112 from the LSI tester 102 like the structure according to claim 3, the characteristic evaluation of the high-speed transmission and reception tests can be performed under various conditions. By the control from the LSI tester 102, the test can be performed under a plurality of kinds of difficult test conditions.

Moreover, by changing the transmission and reception characteristics of the high-speed interface circuit 112 by controlling the fixed switch on the high-speed interface circuit test module 100 like the structure according to claim 4, the characteristic evaluation of the high-speed transmission and reception tests can be performed under various conditions. By switching the fixed switch after determining the most suitable transmission and reception characteristics, the test condition can be set. Moreover, the control signal from the LSI tester 102 is unnecessary, so that the test time can be reduced although the reduction amount is slight.

Moreover, by providing the communication protocol interface circuit on the high-speed interface circuit test module 100 like the structure according to claim 5, the high-speed signal transmission and reception processing can be performed between the communication protocol interface circuit and the reference LSI 108 only by a simple control signal from the tester 102 to the communication protocol interface circuit, so that a complicated test pattern from the LSI tester 102 is unnecessary.

Moreover, by adopting the structure according to claim 6, the clock generator 111 is unnecessary on the high-speed interface circuit test module 100, so that the production cost of the high-speed interface circuit test module 100 can be reduced and a periodic diagnosis of the clock generator 111 is unnecessary.

Further, by using the method according to claim 22, the transmission test and the reception test can be performed at a time, so that the test time can be reduced.

Moreover, by making the high-speed interface circuit test module 100 disconnectable from the load board 103 by the second connector 109 for low-speed signal communication, the high-speed interface circuit test module 100 can be used for various kinds of LSI testers.

While the present embodiment is described with the focus placed on the transmission and reception tests of the high-speed interface circuit 104, by connecting all the pins except the high-speed pin of the LSI under test to the LSI tester 102, the function test of other circuits and the DC test of leakage current or the like can be performed when LSIs are mass-produced.

The present embodiment is applicable to the test of the high-speed interface circuits of IEEE 1394, USB, Serial-ATA and the like. For example, in the test of an LSI provided with Serial-ATA 1.0a, with respect to the signal speed 1.5 Gbps of the high-speed interface part, by a method such that the transmission and reception data speed-converted into the low-speed signal by the high-speed interface circuit is temporarily stored in the memory of the LSI or the like, the test can be realized with the operating frequency of the LSI tester not more than several Mbps or several kbps. Consequently, the mass production test can be realized by an inexpensive LSI tester without the use of an expensive LSI tester capable of interfacing at 1.5 Gbps.

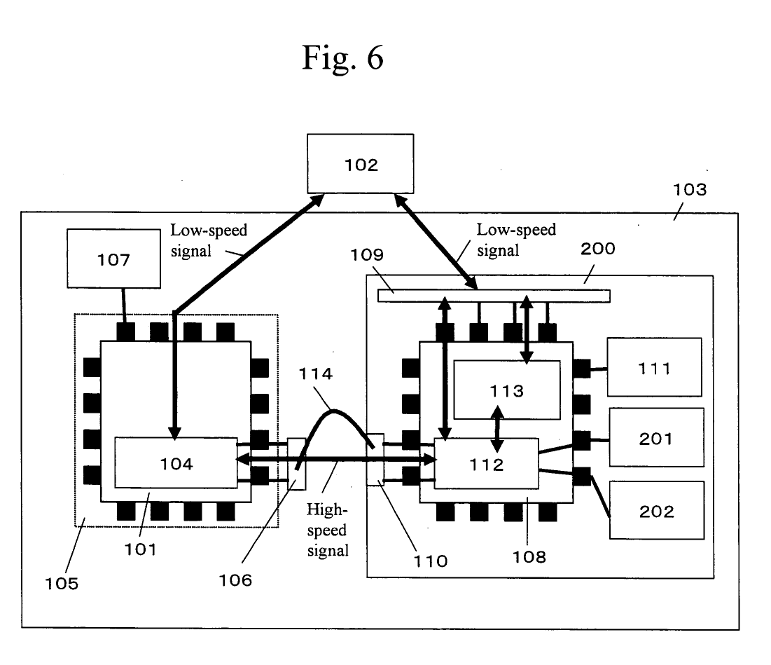

A second embodiment of the present invention will be described with reference to FIG. 6. As the second embodiment, an embodiment according to claims 7, 23 and 24 will be described. FIG. 6 shows the structure of an LSI test using a high-speed interface circuit test module 200 according to the second embodiment of the present invention. Circuits having the same functions as those of the first embodiment are denoted by the same reference numerals.

The structure of this embodiment is different from that of the first embodiment in that a pattern generator 201 and a pattern comparator 202 are newly provided on the high-speed interface circuit test module 200. The pattern generator 201 connected to, of the signal terminals of the reference LSI 108, the input terminal necessary for the access to the high-speed interface circuit 112 by the low-speed signal is a circuit that inputs, to the high-speed interface circuit 112, a test pattern of the low-speed signal which is the source of the high-speed signal transmitted from the high-speed interface circuit 112. The pattern generator 201 may be connected to the signal port of the second connector 109 for low-speed signal communication so that the test pattern of the low-speed signal can be inputted from the LSI tester 102 to the pattern generator 201. The pattern comparator 202 connected to, of the signal terminals of the reference LSI 108, the output terminal necessary for the access to the high-speed interface circuit 112 by the low-speed signal is a circuit that captures the reception data of the low-speed signal outputted from the high-speed interface circuit 112 or the like and compares it with the expected value pattern. Moreover, the pattern comparator 202 is connected to the signal port of the second connector 109 for low-speed signal communication, and performs the processing to transmit the signal representative of the determination result of the comparison with the expected value to the LSI tester 102. A structure may be adopted such that the expected value pattern can be inputted from the LSI tester 102 to the pattern comparator 202. Further, the high-speed interface circuit test module 200 may have a structure such that the structures and functions of the pattern generator 201 and the pattern comparator 202 are independent of each other and both or either one is provided. Moreover, the clock supply to the pattern generator 201 and the pattern comparator 202 is performed from the output clock from the reference LSI 108, or a clock generator, the LSI tester 102 or the like on the high-speed interface circuit test module 200.

The power supply to the devices is performed from the LSI tester 102 (the above-described is the structure according to claim 7).

Next, an LSI test method using the high-speed interface circuit test module 200 of the embodiment of the present invention will be described. Although the LSI control flow is as shown in any of FIGS. 2, 3 and 4, the object of control is somewhat different from that of the first embodiment.

First, a reception test of the high-speed interface circuit 104 of the LSI under test 101 will be described. The control flow of this test is similar to that shown in FIG. 2. This test method is different from that of the first embodiment in that the processing to input, to the reference LSI 108, a test pattern of the low-speed signal for data transmission from the pattern generator 201 provided on the high-speed interface circuit test module 200 is performed.

A predetermined test voltage is supplied from the LSI tester 102 to the power terminals and the input terminals of the LSI under test 101 and the reference LSI 108 (S1), and a reset signal is supplied. Moreover, the clock signal is supplied to the LSI under test 101 and the reference LSI 108 by the clock generator 107 and the clock generator 111 (S2). The clock signal may be supplied from the LSI tester 102 by way of the load board 103 and the second connector 109 for low-speed signal communication. Then, the high-speed interface circuit 104 of the LSI under test 101 and the high-speed interface circuit 112 of the reference LSI 108 on the high-speed interface circuit test module 200 are accessed from the LSI tester 102 by the low-speed signal, and the reception setting and the transmission setting are made thereon (S3). Moreover, for the characteristic control register circuit 113, a desired register setting is made on the characteristic control register circuit 113 by the input of the control signal from the LSI tester 102, by the input of the control signal by the fixed switching circuit, or by use of the set values of the transmission and reception characteristics of the initial condition of the characteristic control register circuit 113 without any external control, whereby the transmission characteristic of the driver circuit of the high-speed interface circuit 112 is set so as to be changed (S4). For example, the amplitude of the voltage which is the output signal from the driver is increased or decreased by changing the output current amount of the driver circuit, or the following setting is made: the setting to shift the common mode level intermediate between the high level and the low level from the ideal potential; or the setting where the transmitting end resistance of the driver is variable and signal reflection readily occurs due to an impedance mismatch. This enables the creation of a condition under which it is difficult for the receiver circuit of the high-speed interface circuit 104 of the LSI under test 101 to receive the high-speed signal. The transmission setting of the high-speed interface circuit 112 and the setting of the characteristic of transmission to the characteristic control register circuit 113 may be controlled by use of the communication protocol interface circuit.

Then, a test pattern of the low-speed signal for data transmission is inputted from the pattern generator 201 to the reference LSI 108 by the control signal from the LSI tester 102, the communication protocol interface circuit or the reference LSI 108 (S5). At this time, it is necessary for the pattern generator 201 to transmit data in synchronism with the input timing of the reference LSI 108. For this reason, for example, by adopting a method such that an internal clock is outputted from the reference LSI 108 and inputted to the pattern generator 201, data is transmitted with the clock signal of the reference LSI 108 as the reference clock of the pattern generator 201. It is necessary that the test pattern to store data in the pattern generator 201 be previously inputted by use of the LSI tester 102 or an external pattern writer before the present test is performed. When the transmission and reception tests are performed on one LSI under test 101 by use of a plurality of kinds of transmission data, a test pattern of the transmission data may be inputted from the LSI tester to the pattern generator 201 every test. Since this enables the reception test to be performed by use of a plurality of kinds of transmission data, a condition can be created under which it is difficult for the receiver circuit of the high-speed interface circuit 104 of the LSI under test 101 to receive the high-speed signal (the method according to claim 24).

Then, the test pattern for data transmission is converted into the high-speed signal by serializing or the like at the high-speed interface circuit 112 of the reference LSI 108, and the high-speed signal is transmitted from the driver circuit (S6). The high-speed signal passes through the first connector 110 provided specifically for the high-speed interface, the high-speed-interface-specific cable 114 and the third connector 106 provided specifically for the high-speed interface to be inputted to the input terminal of the LSI under test 101. That is, the receiver circuit of the high-speed interface circuit 104 of the LSI under test 101 receives the data of the high-speed signal. The received high-speed signal is converted into the low-speed signal by deserializing or the like at the high-speed interface circuit 104. The LSI tester 102 reads out the reception data converted into the low-speed signal of the high-speed interface circuit 104 (S7). It is necessary for the LSI tester 102 to capture data into the memory of the LSI tester 102 in synchronism with the output timing of the reception data of the LSI under test 101, and as an example, the synchronism is obtained by use of the function of matching the output data with the expected value and the function of capturing digital data into the memory in a predetermined cycle which are functions of the LSI tester. When a FIFO circuit is present within the LSI under test 101, synchronism with the LSI tester 102 is obtained by converting the output timing of the reception data inputted to the FIFO circuit so that the reception data is in synchronism with the external clock, that is, the clock of the LSI tester 102. Lastly, the reception data is compared with the expected value by the LSI tester 102, and it is determined whether the reception test of the LSI under test 101 is good or not (S8).

Next, a transmission test of the high-speed interface circuit 104 of the LSI under test 101 will be described. The control flow of this test is similar to FIG. 3. This test method is different from that of the first embodiment in that the pattern comparator 202 provided on the high-speed interface circuit test module 200 captures the reception data converted into the low-speed signal of the high-speed interface circuit 112 and the LSI tester 102 performs the processing to read out the comparison result from the pattern comparator 202.

A predetermined test voltage is supplied from the LSI tester 102 to the power terminals and the input terminals of the LSI under test 101 and the reference LSI 108 (S1), and a reset signal is supplied. Moreover, the clock signal is supplied to the LSI under test 101 and the reference LSI 108 by the clock generator 107 and the clock generator 111 (S2). The clock signal may be supplied from the LSI tester 102 by way of the load board 103 and the second connector 109 for low-speed signal communication. Then, the high-speed interface circuit 104 of the LSI under test 101 and the high-speed interface circuit 112 of the reference LSI 108 on the high-speed interface circuit test module 200 are accessed from the LSI tester 102 by the low-speed signal, and the transmission setting and the reception setting are made thereon (S3). Moreover, for the characteristic control register circuit 113, a desired register setting is made on the characteristic control register circuit 113 by the input of the control signal from the LSI tester 102, by the input of the control signal by the fixed switching circuit, or by use of the set values of the transmission and reception characteristics of the initial condition without any external control, whereby the reception characteristic of the driver circuit of the high-speed interface circuit 112 is set so as to be changed (S4). For example, the following setting is made: the setting to decrease the amplitude of the voltage that can be received by the receiver by changing the detection current value and the detection reference voltage value of the receiver circuit; the setting to shift the common mode voltage intermediate between the high level and the low level from the ideal potential by changing the amount of pull-in current of the receiver circuit; or the setting where the terminating resistance of the receiver is variable and signal reflection readily occurs due to an impedance mismatch. This enables the creation of a condition under which it is difficult for the driver circuit of the high-speed interface circuit 104 of the LSI under test 101 to transmit the high-speed signal. The reception setting of the high-speed interface circuit 112 and the reception characteristic setting to the characteristic control register circuit 113 may be controlled by use of the communication protocol interface circuit.

Then, a test pattern of the low-speed signal for data transmission is inputted from the LSI tester 102 to the LSI under test 101 (S5). The test pattern for data transmission is converted into the high-speed signal by serializing or the like at the high-speed interface circuit 104 of the LSI under test 101, and the high-speed signal is transmitted from the driver circuit (S6). The high-speed signal passes through the third connector 106 provided specifically for the high-speed interface, the high-speed-interface-specific cable 114 and the first connector 110 provided specifically for the high-speed interface to be inputted to the input terminal of the reference LSI 108. That is, the receiver circuit of the high-speed interface circuit 112 of the reference LSI 108 receives the data of the high-speed signal. The received high-speed signal is converted into the low-speed signal by deserializing or the like at the high-speed interface circuit 112. Then, the reception data converted into the low-speed signal which data is outputted from the high-speed interface circuit 112 is stored into the memory of the pattern comparator 202, for example, by the reception data capturing method like the above-mentioned functions of the LSI tester 102 (S7). At this time, it is necessary for the pattern comparator 202 to capture data in synchronism with the output timing of the reception data of the high-speed interface circuit 112. For this reason, for example, by adopting a method such that an internal clock is outputted from the reference LSI 108 and inputted to the pattern comparator 202, data is captured with the clock signal of the reference LSI 108 as the reference clock of the pattern comparator 202. It is necessary that the expected value pattern stored in the pattern comparator 202 be previously inputted by use of the LSI tester 102 or an external pattern writer before the present test is performed. When the transmission and reception tests are performed on one LSI under test 101 by use of a plurality of kinds of transmission data, an expected value pattern of the reception data may be inputted from the LSI tester to the pattern comparator 202 every test. Since this enables the transmission test to be performed by use of a plurality of kinds of transmission data, a condition can be created under which it is difficult for the driver circuit of the high-speed interface circuit 104 of the LSI under test 101 to transmit the high-speed signal (the method according to claim 24). Lastly, the pattern comparator 202 transmits the comparison result of the expected value to the LSI tester 102, and it is determined whether the transmission test of the LSI under test 101 is good or not (S8).

While the reception test and the transmission test of the LSI under test 101 are separately described, when a loopback function is provided within the LSI under test 101, that is, when the function of transmitting the data received by the receiver circuit to the driver circuit as it is through deserializing and serializing is provided, the reception test and the transmission test may be performed at a time. The control flow of the present test is similar to that of FIG. 4.

A predetermined test voltage is supplied from the LSI tester 102 to the power terminals and the input terminals of the LSI under test 101 and the reference LSI 108 (S1), and a reset signal is supplied. Moreover, the clock signal is supplied to the LSI under test 101 and the reference LSI 108 by the clock generator 107 and the clock generator 111 (S2). The clock signal may be supplied from the LSI tester 102 by way of the load board 103 and the second connector 109 for low-speed signal communication. Then, the high-speed interface circuit 104 of the LSI under test 101 and the high-speed interface circuit 112 of the reference LSI 108 on the high-speed interface circuit test module 200 are accessed from the LSI tester 102 by the low-speed signal, and the transmission and reception setting is made thereon (S3). Further, the setting to perform a loopback operation is made on the LSI under test 101 (S4).

Then, a test pattern of the low-speed signal for data transmission is inputted from the pattern generator 201 to the reference LSI 108 by the control signal from the LSI tester 102, the communication protocol interface circuit or the reference LSI 108 (S6). At this time, it is necessary for the pattern generator 201 to transmit data in synchronism with the input timing of the reference LSI 108. For this reason, for example, by adopting a method such that an internal clock is outputted from the reference LSI 108 and inputted to the pattern generator 201, data is transmitted with the clock signal of the reference LSI 108 as the reference clock of the pattern generator 201. It is necessary that the test pattern stored in the pattern generator 201 be previously inputted by use of the LSI tester 102 or an external pattern writer before the present test is performed. When the transmission and reception tests are performed on one LSI under test 101 by use of a plurality of kinds of transmission data, a test pattern of the transmission data may be inputted from the LSI tester to the pattern generator 201 every test. Since this enables the transmission and reception tests to be performed by use of a plurality of kinds of transmission data, a condition can be created under which it is difficult for the receiver circuit of the high-speed interface circuit 104 of the LSI under test 101 to receive the high-speed signal (the method according to claim 24).

Then, after the high-speed signal transmitted from the high-speed interface circuit 112 of the reference LSI 108 is received by the receiver circuit of the high-speed interface circuit 104 and converted into the low-speed signal by deserializer or the like, the converted low-speed data is converted into the high-speed signal by a serializer or the like by way of the path of a loopback for transfer to the driver side, and the converted high-speed signal is transmitted from the driver circuit to the reference LSI 108 (S7). By making a desired register setting on the characteristic control register circuit 113, the transmission characteristic and the reception characteristic of the driver circuit of the high-speed interface circuit 112 are set to as to be changed, and by doing this, a condition is created under which it is difficult for the receiver circuit of the high-speed interface circuit 104 of the LSI under test 101 to receive the high-speed signal. Then, the reception data converted into the low-speed signal which data is outputted from the high-speed interface circuit 112 is stored into the memory of the pattern comparator 202, for example, by the reception data capturing method like the above-mentioned functions of the LSI tester 102. At this time, it is necessary for the pattern comparator 202 to capture data in synchronism with the output timing of the reception data of the high-speed interface circuit 112. For this reason, for example, by adopting a method such that an internal clock is outputted from the reference LSI 108 and inputted to the pattern comparator 202, data is captured with the clock signal of the reference LSI 108 as the reference clock of the pattern comparator 202. By a method such as the above-described reception data capturing method by the LSI tester 102, data is captured into the memory of the pattern comparator 202 in synchronism with the output timing of the reception data of the high-speed interface circuit 112 (S8). It is necessary that the expected value pattern stored in the pattern comparator 202 be previously inputted by use of the LSI tester 102 or an external pattern writer before the present test is performed. When the transmission and reception tests are performed on one LSI under test 101 by use of a plurality of kinds of transmission data, an expected value pattern of the reception data may be inputted from the LSI tester to the pattern comparator 202 every test. Since this enables the transmission and reception tests to be performed by use of a plurality of kinds of transmission data, a condition can be created under which it is difficult for the receiver circuit of the high-speed interface circuit 104 of the LSI under test 101 to transmit the high-speed signal (the method according to claim 24).

Lastly, the pattern comparator 202 transmits the result of the comparison with the expected value to the LSI tester 102, and it is determined whether the reception and transmission tests of the LSI under test 101 are good or not (S9) (the above-described is the method according to claim 23).

As described above, by using the high-speed interface circuit test module 200 of the embodiment of the present invention, in the transmission and reception tests of the high-speed interface circuit 104 that interfaces by the high-speed signal, by arbitrarily setting from the outside the transmission and reception characteristics of the driver, the receiver and the like of the high-speed interface circuit 112 of the reference LSI 108 which is the object of the transmission and reception of the LSI under test 101, a difficult condition for the LSI under test 101 to perform the transmission or reception of the high-speed signal can be created.

Moreover, by performing the test by providing the high-speed interface circuit test module 200 with the pattern generator 201 and the pattern comparator 202 like the structure according to claim 7 and the method according to claim 23, it is unnecessary to use a tester function such as the above-described matching function or digital capturing function of the LSI tester which function is necessary for the LSI tester 102 to obtain synchronism with the input and output of the low-speed signal of the LSI under test 101 and the reference LSI, so that the creation of the test program and the test pattern of the LSI tester 102 is facilitated.

Moreover, by switching the data stored in the pattern generator 201 and the pattern comparator 202 to a necessary signal every test like the method according to claim 24, the transmission test can be performed by use of a plurality of kinds of transmission data, so that a plurality of kinds of difficult conditions for the LSI under test 101 to transmit or receive the high-speed signal can be created.

Further, since the test can be realized by the interface of only the low-speed signal with the LSI tester 102, the mass production test of the high-speed interface can be realized only by an inexpensive LSI tester that interfaces at low speed and the high-speed interface circuit test module 200 of the simple structure disposed on the load board 103, so that the test cost can be prevented from increasing.

Moreover, by making the high-speed interface circuit test module 200 disconnectable from the load board 103 by the second connector 109 for low-speed signal communication, the high-speed interface circuit test module 200 can be used for various kinds of LSI testers.

While the present embodiment is described with the focus placed on the transmission and reception tests of the high-speed interface circuit 104, by connecting all the pins except the high-speed pin of the LSI under test to the LSI tester 102, the function test of other circuits and the DC test of leakage current or the like can be performed when LSIs are mass-produced.

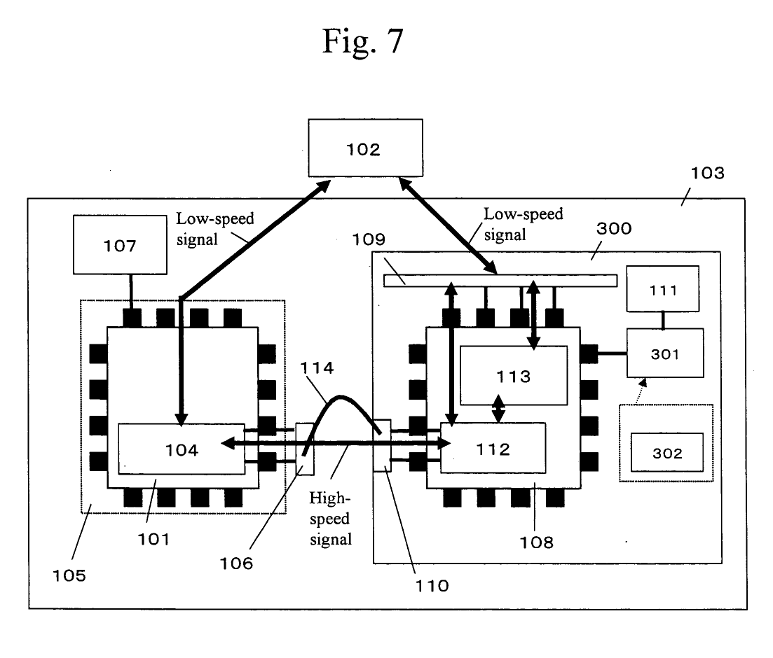

A third embodiment of the present invention will be described with reference to FIG. 7. As the third embodiment, an embodiment according to claims 8, 9 and 10 will be described. FIG. 7 shows the structure of an LSI test using a high-speed interface circuit test module 300 according to the third embodiment of the present invention. Circuits having the same functions as those of the first embodiment are denoted by the same reference numerals.

The structure of this embodiment is different from that of the first embodiment in that a frequency modulator 301 or a jitter injector 302 is newly provided on the high-speed interface circuit test module 300 so as to adjoin the clock generator 111.

The frequency modulator 301 is connected to the output terminal of the clock generator 111 and to the clock input terminal of the reference LSI 108, and supplies a spectrum modulation clock signal. The spectrum modulation clock is a clock whose clock frequency changes at predetermined intervals. The clock modulation frequency and the clock modulation amount of the frequency modulator 301 are variable. The jitter injector 302 is connected to the output terminal of the clock generator 111 and to the clock input terminal of the reference LSI 108, and adds predetermined jitter to the clock signal outputted from the clock generator and outputs it to thereby supply a clock containing a predetermined jitter component to the clock input terminal of the reference LSI 108. The frequency modulator 301 and the jitter injector 302 may have a structure such that they are connected to the signal port of the second connector 109 for low-speed signal communication so that the modulation frequency and the modulation amount of the frequency modulator 301 or the jitter amount of the jitter injector 302 can be arbitrarily changed by a signal from the LSI tester 102 (the structure according to claim 9) or have a structure such that a fixed switch is provided on the high-speed interface circuit test module 300 so that the modulation frequency and the modulation amount of the frequency modulator 301 or the jitter amount of the jitter injector 302 can be arbitrarily changed (the structure according to claim 10).

The power supply to the devices is performed from the LSI tester 102 (the above-described is the structure according to claim 7).

Next, an LSI test method using the high-speed interface circuit test module 300 of the embodiment of the present invention will be described. Although the LSI control flow is as shown in any of FIGS. 2, 3, 4 and 5, the object of control is somewhat different from that of the first embodiment.

First, a reception test of the high-speed interface circuit 104 of the LSI under test 101 will be described. The control flow of this test is similar to that of FIG. 2. This test method is different from that of the first embodiment in that the clock signal is supplied by use of the frequency modulator 301 or the jitter injector 302 provided on the high-speed interface circuit test module 300.

A predetermined test voltage is supplied from the LSI tester 102 to the power terminals and the input terminals of the LSI under test 101 and the reference LSI 108 (S1), and a reset signal is supplied. Moreover, the clock signal is supplied to the LSI under test 101 by the LSI tester 102 or the clock generator 107 (S2). Moreover, with respect to the clock signal outputted from the clock generator 111, a spread spectrum clock signal generated by the passage through the frequency modulator 301 and set to a predetermined modulation frequency and modulation amount is supplied to the reference LSI 108. The clock signal containing a predetermined jitter component generated by the passage through the jitter injector 302 may be supplied to the reference LSI 108 by using the jitter injector 302 instead of the frequency modulator 301. Moreover, the characteristic values of the modulation frequency and the modulation amount of the frequency modulator 301 and the jitter amount of the jitter injector 302 may be arbitrarily set from the outside by the control signal from the LSI tester (the method by the structure according to claim 9). Further, the characteristic values of the modulation frequency and the modulation amount of the frequency modulator 301 and the jitter amount of the jitter injector 302 may be set by the control from the fixed switch constructed on the high-speed interface circuit test module 300 (the method by the structure according to claim 10). Since this enables the high-speed signal transmitted by the high-speed interface circuit 112 of the reference LSI 108 to be frequency-modulated and provided with a jitter component, it is necessary for the receiver circuit to receive data in response to a frequency variation, so that a condition can be creased under which it is difficult for the receiver circuit of the high-speed interface circuit 104 of the LSI under test 101 to receive the high-speed signal (the above-described is the method by the structure according to claim 8).

Then, the high-speed interface circuit 104 of the LSI under test 101 and the high-speed interface circuit 112 of the reference LSI 108 on the high-speed interface circuit test module 300 are accessed from the LSI tester 102 by the low-speed signal, and the reception setting and the transmission setting are made thereon (S3). Moreover, for the characteristic control register circuit 113, a desired register setting is made on the characteristic control register circuit 113 by the input of the control signal from the LSI tester 102, by the input of the control signal by the fixed switching circuit, or by use of the set values of the transmission and reception characteristics of the initial condition of the characteristic control register circuit 113 without any external control, whereby the transmission characteristic of the driver circuit of the high-speed interface circuit 112 is set so as to be changed (S4) For example, the amplitude of the voltage which is the output signal from the driver is increased or decreased by changing the output current amount of the driver circuit, or the following setting is made: the setting to shift the common mode level intermediate between the high level and the low level from the ideal potential; or the setting where the transmitting end resistance of the driver is variable and signal reflection readily occurs due to an impedance mismatch. This enables the creation of a condition under which it is difficult for the receiver circuit of the high-speed interface circuit 104 of the LSI under test 101 to receive the high-speed signal. The transmission setting of the high-speed interface circuit 112 and the transmission characteristic setting to the characteristic control register circuit 113 may be controlled by use of the communication protocol interface circuit.

Then, a test pattern of the low-speed signal for data transmission is inputted from the LSI tester 102 to the reference LSI 108 (S5). The test pattern for data transmission is converted into the high-speed signal by serializing or the like at the high-speed interface circuit 112 of the reference LSI 108, and the high-speed signal is transmitted from the driver circuit (S6). The high-speed signal passes through the first connector 110 provided specifically for the high-speed interface, the high-speed-interface-specific cable 114 and the third connector 106 provided specifically for the high-speed interface to be inputted to the input terminal of the LSI under test 101. That is, the receiver circuit of the high-speed interface circuit 104 of the LSI under test 101 receives the data of the high-speed signal. The received high-speed signal is converted into the low-speed signal by deserializing or the like at the high-speed interface circuit 104. The LSI tester 102 reads out the reception data converted into the low-speed signal of the high-speed interface circuit 104 (S7). It is necessary for the LSI tester 102 to capture data into the memory of the LSI tester 102 in synchronism with the output timing of the reception data of the LSI under test 101, and as an example, the synchronism is obtained by use of the function of matching the output data with the expected value and the function of capturing digital data into the memory in a predetermined cycle which are functions of the LSI tester. When a FIFO circuit is present within the LSI under test 101, synchronism with the LSI tester is obtained by converting the output timing of the reception data inputted to the FIFO circuit so that the reception data is in synchronism with the external clock, that is, the clock of the LSI tester 102. Lastly, the reception data is compared with the expected value by the LSI tester 102, and it is determined whether the reception test of the LSI under test 101 is good or not (S8).

Next, a transmission test of the high-speed interface circuit 104 of the LSI under test 101 will be described. The control flow of this test is similar to that of FIG. 3. This test method is different from that of the first embodiment in that the clock signal is supplied by use of the frequency modulator 301 or the jitter injector 302 provided on the high-speed interface circuit test module 300.

A predetermined test voltage is supplied from the LSI tester 102 to the power terminals and the input terminals of the LSI under test 101 and the reference LSI 108 (S1), and a reset signal is supplied. Moreover, the clock signal is supplied to the LSI under test 101 by the LSI tester 102 or the clock generator 107 (S2). Moreover, with respect to the clock signal outputted from the clock generator 111, a spread spectrum clock signal generated by the passage through the frequency modulator 301 or the jitter injector 302 and set to a predetermined modulation frequency and modulation amount or the clock signal containing a predetermined jitter component is supplied to the reference LSI 108 (the method by the structure according to claim 8). Moreover, the characteristic values of the modulation frequency and the modulation amount of the frequency modulator 301 and the jitter amount of the jitter injector 302 may be arbitrarily set from the outside by the control signal from the LSI tester (the method by the structure according to claim 9). Further, the characteristic values of the modulation frequency and the modulation amount of the frequency modulator 301 and the jitter amount of the jitter injector 302 may be set by the control from the fixed switch constructed on the high-speed interface circuit test module 300 (the method by the structure according to claim 10). Since this makes it necessary for the receiver circuit operating on the frequency-modulated clock containing the jitter component to receive the high-speed signal transmitted from the LSI under test 101 in the high-speed interface circuit 112 of the reference LSI 108, so that a condition can be created under which it is difficult for the driver circuit of the high-speed interface circuit 104 of the LSI under test 101 to transmit the high-speed signal (the above-described is the method by the structure according to claim 8).

Then, the high-speed interface circuit 104 of the LSI under test 101 and the high-speed interface circuit 112 of the reference LSI 108 on the high-speed interface circuit test module 300 are accessed from the LSI tester 102 by the low-speed signal, and the transmission setting and the reception setting are made thereon (S3). Moreover, for the characteristic control register circuit 113, a desired register setting is made on the characteristic control register circuit 113 by the input of the control signal from the LSI tester 102, by the input of the control signal by the fixed switching circuit, or by use of the set values of the transmission and reception characteristics of the initial condition without any external control, whereby the reception characteristic of the driver circuit of the high-speed interface circuit 112 is set so as to be changed (S4) For example, the following setting is made: the setting to decrease the amplitude of the voltage that can be received by the receiver by changing the detection current value and the detection reference voltage value of the receiver circuit; the setting to shift the common mode voltage intermediate between the high level and the low level from the ideal potential by changing the amount of pull-in current of the receiver circuit; or the setting where the terminating resistance of the receiver is variable and signal reflection readily occurs due to an impedance mismatch. This enables the creation of a condition under which it is difficult for the driver circuit of the high-speed interface circuit 104 of the LSI under test 101 to transmit the high-speed signal. The reception setting of the high-speed interface circuit 112 and the reception characteristic setting to the characteristic control register circuit 113 may be controlled by use of the communication protocol interface circuit.

Then, a test pattern of the low-speed signal for data transmission is inputted from the LSI tester 102 to the LSI under test 101 (S5). The test pattern for data transmission is converted into the high-speed signal by serializing or the like at the high-speed interface circuit 104 of the LSI under test 101, and the high-speed signal is transmitted from the driver circuit (S6). The high-speed signal passes through the third connector 106 provided specifically for the high-speed interface, the high-speed-interface-specific cable 114 and the first connector 110 provided specifically for the high-speed interface to be inputted to the input terminal of the reference LSI 108. That is, the receiver circuit of the high-speed interface circuit 112 of the reference LSI 108 receives the data of the high-speed signal. The received high-speed signal is converted into the low-speed signal by deserializing or the like at the high-speed interface circuit 112. The LSI tester 102 reads out the reception data converted into the low-speed signal of the high-speed interface circuit 112 (S7). By a method such as the above-described reception data capturing method by the functions of the LSI tester 102 or the like, data is captured into the memory of the LSI tester 102 in synchronism with the output timing of the reception data of the high-speed interface circuit 112. Lastly, the reception data is compared with the expected value by the LSI tester 102, and it is determined whether the transmission test of the LSI under test 101 is good or not (S8).

Embodiments for FIGS. 4 and 5 are omitted because the contents associated with the frequency modulator 301 and the jitter injector 302 which contents are newly described in the present embodiment are the same as those described above.

As described above, by using the high-speed interface circuit test module 300 provided with the frequency modulator 301 and the jitter injector 302 like the structure according to claim 8 of the present invention, in the transmission and reception tests of the high-speed interface circuit 104 that interfaces by the high-speed signal, the transmission and reception characteristics of the driver, the receiver and the like of the high-speed interface circuit 112 of the reference LSI 108 which is the object of the transmission and reception of the LSI under test 101 can be arbitrarily changed from the outside and the clock characteristic can be arbitrarily set from the outside by the frequency modulator 301 and the jitter injector 302, so that a difficult condition for the LSI under test 101 to perform the transmission or reception of the high-speed signal can be created.

Moreover, by changing the characteristic values of the modulation frequency and the modulation amount of the frequency modulator 301 or the jitter amount of the jitter injector 302 from the LSI tester 102 like the structure according to claim 9, the characteristic evaluation of the high-speed transmission and reception tests can be performed under various conditions. Then, by the control from the LSI tester 102, the test can be performed under a plurality of kinds of difficult conditions.

By changing the characteristic values of the modulation frequency and the modulation amount of the frequency modulator 301 or the jitter amount of the jitter injector 302 by controlling the fixed switch on the high-speed interface circuit test module 300 like the structure according to claim 10, the characteristic evaluation of the high-speed transmission and reception tests can be performed under various conditions. Then, by switching the fixed switch after determining the most suitable transmission and reception characteristics, the test condition can be set. Moreover, the control signal from the LSI tester 102 is unnecessary, so that the test time can be reduced although the reduction amount is slight.

Further, since the test can be realized by the interface of only the low-speed signal with the LSI tester 102, the mass production test of the high-speed interface can be realized only by an inexpensive LSI tester that interfaces at low speed and the high-speed interface circuit test module 300 of the simple structure disposed on the load board 103, so that the test cost can be prevented from increasing.

Moreover, by making the high-speed interface circuit test module 300 disconnectable from the load board 103 by the second connector 109 for low-speed signal communication, the high-speed interface circuit test module 300 can be used for various kinds of LSI testers.

While the present embodiment is described with the focus placed on the transmission and reception tests of the high-speed interface circuit 104, by connecting all the pins except the high-speed pin of the LSI under test to the LSI tester 102, the function test of other circuits and the DC test of leakage current or the like can be performed when LSIs are mass-produced.

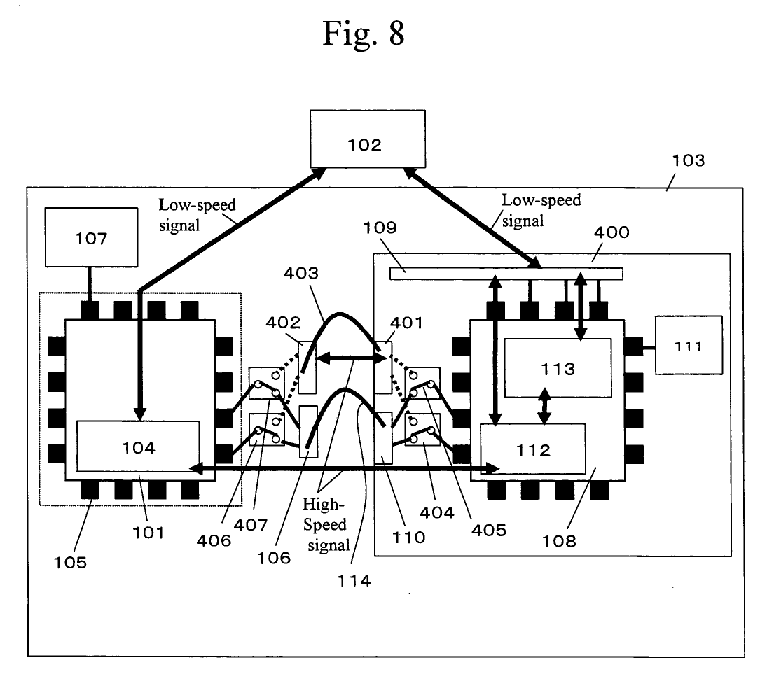

A fourth embodiment of the present invention will be described with reference to FIG. 8. As the fourth embodiment, an embodiment according to claims 11 and 25 will be described. FIG. 8 shows the structure of an LSI test using a high-speed interface circuit test module 400 according to the fourth embodiment of the present invention. Circuits having the same functions as those of the first embodiment are denoted by the same reference numerals.

The structure of this embodiment is different from that of the first embodiment in that a fifth connector 401 provided specifically for the high-speed interface, a first relay 404 and a second relay 405 are newly provided on the high-speed interface circuit test module 400 and a sixth connector 402 provided specifically for the high-speed interface, a second cable 403 provided specifically for the high-speed interface, a third relay 406 and a fourth relay 407 are newly provided on the load board 103.

The fifth connector 401 provided specifically for the high-speed interface is connected to the high-speed signal input and output terminals of the reference LSI 108 through pattern wiring like the first connector 110 provided specifically for the high-speed interface. The first relay 404 and the second relay 405 are disposed in order to switch the connector to which the high-speed signal input and output terminals of the reference LSI 108 is connected between the first connector 110 provided specifically for the high-speed interface and the fifth connector 401 provided specifically for the high-speed interface. The first relay 404 has its one end connected to the high-speed signal input terminal of the reference LSI 108 and has its other end connected to the first connector 110 provided specifically for the high-speed interface and the fifth connector 401 provided specifically for the high-speed interface. Moreover, the second relay 405 has its one end connected to the high-speed signal output terminal of the reference LSI 108 and has its other end connected to the first connector 110 provided specifically for the high-speed interface and the fifth connector 401 provided specifically for the high-speed interface. Moreover, the first relay 404 and the second relay 405 are connected to the second connector for low-speed signal communication, and a control signal port for switching the signal directions of the first relay 404 and the second relay 405 is provided on the second connector for low-speed signal communication. One terminal of the second cable 403 provided specifically for the high-speed interface is connected to the fifth connector 401 provided specifically for the high-speed interface.

Moreover, on the load board 103, the third relay 406, the fourth relay 407, the third connector 106 provided specifically for the high-speed interface and the sixth connector 402 provided specifically for the high-speed interface are disposed in the vicinity of the high-speed signal input and output terminals of the high-speed interface circuit 104 of the LSI under test 101. The sixth connector 402 provided specifically for the high-speed interface is connected to the high-speed signal input and output terminals of the LSI under test 101 through pattern wiring like the third connector 106 provided specifically for the high-speed interface. The third relay 406 and the fourth relay 407 are used in order to switch the connector to which the high-speed signal input and output terminals of the LSI under test 101 is connected between the third connector 106 provided specifically for the high-speed interface and the sixth connector 402 provided specifically for the high-speed interface. The third relay 406 has its one end connected to the high-speed signal output terminal of the LSI under test 101 and has its other end connected to the third connector 106 provided specifically for the high-speed interface and the sixth connector 402 provided specifically for the high-speed interface. Moreover, the fourth relay 407 has its one end connected to the high-speed signal input terminal of the LSI under test 101 and has its other end connected to the third connector 106 provided specifically for the high-speed interface and the sixth connector 402 provided specifically for the high-speed interface. Moreover, the control signal terminal for switching the signal directions of the third relay 406 and the fourth relay 407 is connected to the LSI tester 102. Moreover, one terminal of the second cable 403 provided specifically for the high-speed interface is connected to the sixth connector 402 provided specifically for the high-speed interface. While the numbers of connectors provided specifically for the high-speed interface and switching relays are two in this example, the numbers may be three or more.

The power supply to the devices is performed from the LSI tester 102 (the above-described is the structure according to claim 11).

Next, an LSI test method using the high-speed interface circuit test module 400 of the embodiment of the present invention will be described. Although the LSI control flow is as shown in any of FIGS. 2, 3, 4 and 5, the object of control is somewhat different from that of the first embodiment.

First, a reception test of the high-speed interface circuit 104 of the LSI under test 101 will be described. The control flow of this test is similar to that of FIG. 2. This test method is different from that of the first embodiment in that a control is performed for switching the cable through which the high-speed signal is transmitted between the high-speed signal input and output terminals of the high-speed interface circuit 104 of the LSI under test 101 and the high-speed signal input and output terminals of the high-speed interface circuit 112 of the reference LSI 108.

A predetermined test voltage is supplied from the LSI tester 102 to the power terminals and the input terminals of the LSI under test 101 and the reference LSI 108 (S1), and a reset signal is supplied. Moreover, the clock signal is supplied to the LSI under test 101 and the reference LSI 108 by the clock generator 107 and the clock generator 111 (S2). The clock signal may be supplied from the LSI tester 102 by way of the load board 103 and the second connector 109 for low-speed signal communication. Moreover, the connection directions of the first relay 404, the second relay 405, the third relay 406 and the fourth relay 407 are controlled from the LSI tester 102 to thereby select which of the high-speed-interface-specific cable 114 and the second cable provided specifically for the high-speed interface is used to transmit the signal. For two cables, the high-speed-interface-specific cable 114 and the second cable 403 provided specifically for the high-speed interface, cables having different high-speed signal transmission characteristics such as the cable length and the characteristic impedance are previously selected and the test is performed by use of the cables, whereby a plurality of conditions or a difficult condition for the receiver circuit of the high-speed interface circuit 104 of the LSI under test 101 to receive the high-speed signal can be created. Then, the high-speed interface circuit 104 of the LSI under test 101 and the high-speed interface circuit 112 of the reference LSI 108 on the high-speed interface circuit test module 400 are accessed from the LSI tester 102 by the low-speed signal, and the reception setting and the transmission setting are made thereon (S3). Moreover, for the characteristic control register circuit 113, a desired register setting is made on the characteristic control register circuit 113 by the input of the control signal from the LSI tester 102, by the input of the control signal by the fixed switching circuit, or by use of the set values of the transmission and reception characteristics of the initial condition of the characteristic control register circuit 113 without any external control, whereby the transmission characteristic of the driver circuit of the high-speed interface circuit 112 is set so as to be changed (S4). For example, the amplitude of the voltage which is the output signal from the driver is increased or decreased by changing the output current amount of the driver circuit, or the following setting is made: the setting to shift the common mode level intermediate between the high level and the low level from the ideal potential; or the setting where the transmitting end resistance of the driver is variable and signal reflection readily occurs due to an impedance mismatch. This enables the creation of a condition under which it is difficult for the receiver circuit of the high-speed interface circuit 104 of the LSI under test 101 to receive the high-speed signal. The transmission setting of the high-speed interface circuit 112 and the transmission characteristic setting to the characteristic control register circuit 113 may be controlled by use of the communication protocol interface circuit.

Then, a test pattern of the low-speed signal for data transmission is inputted from the LSI tester 102 to the LSI under test 101 (S5). The test pattern for data transmission is converted into the high-speed signal by serializing or the like at the high-speed interface circuit 112 of the reference LSI 108, and the high-speed signal is transmitted from the driver circuit (S6). The high-speed signal passes through the first connector 110 provided specifically for the high-speed interface, the high-speed-interface-specific cable 114 and the third connector 106 provided specifically for the high-speed interface to be inputted to the input terminal of the LSI under test 101. That is, the receiver circuit of the high-speed interface circuit 104 of the LSI under test 101 receives the data of the high-speed signal. The received high-speed signal is converted into the low-speed signal by deserializing or the like at the high-speed interface circuit 104. The LSI tester 102 reads out the reception data converted into the low-speed signal of the high-speed interface circuit 104 (S7). It is necessary for the LSI tester 102 to capture data into the memory of the LSI tester 102 in synchronism with the output timing of the reception data of the LSI under test 101, and as an example, the synchronism is obtained by use of the function of matching the output data with the expected value and the function of capturing digital data into the memory in a predetermined cycle which are functions of the LSI tester. When a FIFO circuit is present within the LSI under test 101, synchronism with the LSI tester is obtained by converting the output timing of the reception data inputted to the FIFO circuit so that the reception data is in synchronism with the external clock, that is, the clock of the LSI tester 102. Lastly, the reception data is compared with the expected value by the LSI tester 102, and it is determined whether the reception test of the LSI under test 101 is good or not (S8).

Next, a transmission test of the high-speed interface circuit 104 of the LSI under test 101 will be described. The control flow of this test is similar to that of FIG. 3. This test method is different from that of the first embodiment in that a control is performed for switching the cable through which the high-speed signal is transmitted between the high-speed signal input and output terminals of the high-speed interface circuit 104 of the LSI under test 101 and the high-speed signal input and output terminals of the high-speed interface circuit 112 of the reference LSI 108.

A predetermined test voltage is supplied from the LSI tester 102 to the power terminals and the input terminals of the LSI under test 101 and the reference LSI 108 (S1), and a reset signal is supplied. Moreover, the clock signal is supplied to the LSI under test 101 and the reference LSI 108 by the clock generator 107 and the clock generator 111 (S2). The clock signal may be supplied from the LSI tester 102 by way of the load board 103 and the second connector 109 for low-speed signal communication. Moreover, the connection directions of the first relay 404, the second relay 405, the third relay 406 and the fourth relay 407 are controlled from the LSI tester 102 to thereby select which of the high-speed-interface-specific cable 114 and the second cable provided specifically for the high-speed interface is used to transmit the signal. For two cables, the high-speed-interface-specific cable 114 and the second cable provided specifically for the high-speed interface, cables having different high-speed signal transmission characteristics such as the cable length and the characteristic impedance are previously selected and the test is performed by use of the cables, whereby a plurality of conditions or a difficult condition for the receiver circuit of the high-speed interface circuit 104 of the LSI under test 101 to transmit the high-speed signal can be created. Then, the high-speed interface circuit 104 of the LSI under test 101 and the high-speed interface circuit 112 of the reference LSI 108 on the high-speed interface circuit test module 400 are accessed from the LSI tester 102 by the low-speed signal, and the transmission setting and the reception setting are made thereon (S3). Moreover, for the characteristic control register circuit 113, a desired register setting is made on the characteristic control register circuit 113 by the input of the control signal from the LSI tester 102, by the input of the control signal by the fixed switching circuit, or by use of the set values of the transmission and reception characteristics of the initial condition without any external control, whereby the reception characteristic of the driver circuit of the high-speed interface circuit 112 is set so as to be changed (S4). For example, the following setting is made: the setting to decrease the amplitude of the voltage that can be received by the receiver by changing the detection current value and the detection reference voltage value of the receiver circuit; the setting to shift the common mode voltage intermediate between the high level and the low level from the ideal potential by changing the amount of pull-in current of the receiver circuit; or the setting where the terminating resistance of the receiver is variable and signal reflection readily occurs due to an impedance mismatch. This enables the creation of a condition under which it is difficult for the driver circuit of the high-speed interface circuit 104 of the LSI under test 101 to transmit the high-speed signal. The reception setting of the high-speed interface circuit 112 and the reception characteristic setting to the characteristic control register circuit 113 may be controlled by use of the communication protocol interface circuit. Then, a test pattern of the low-speed signal for data transmission is inputted from the LSI tester 102 to the LSI under test 101 (S5). The test pattern for data transmission is converted into the high-speed signal by serializing or the like at the high-speed interface circuit 104 of the LSI under test 101, and the high-speed signal is transmitted from the driver circuit (S6). The high-speed signal passes through the third connector 106 provided specifically for the high-speed interface, the high-speed-interface-specific cable 114 and the first connector 110 provided specifically for the high-speed interface to be inputted to the input terminal of the reference LSI 108. That is, the receiver circuit of the high-speed interface circuit 112 of the reference LSI 108 receives the data of the high-speed signal. The received high-speed signal is converted into the low-speed signal by deserializing or the like at the high-speed interface circuit 112. The LSI tester 102 reads out the reception data converted into the low-speed signal of the high-speed interface circuit 112 (S7). By a method such as the above-described reception data capturing method by the functions of the LSI tester 102 or the like, data is captured into the memory of the LSI tester 102 in synchronism with the output timing of the reception data of the high-speed interface circuit 112. Lastly, the reception data is compared with the expected value by the LSI tester 102, and it is determined whether the transmission test of the LSI under test 101 is good or not (S8).

Embodiments for FIGS. 4 and 5 are omitted because the contents associated with the use of the high-speed-interface-specific cable 114 and the second cable 403 provided specifically for the high-speed interface which contents are newly described in the present embodiment are the same as those described above (the above-described is the structure according to claim 25).

As described above, by using the high-speed interface circuit test module 400 provided with a plurality of high-speed signal transmission lines such as the high-speed-interface-specific cable 114 and the second cable 403 provided specifically for the high-speed interface like the structure according to claim 11 and the method according to claim 25, in the transmission and reception tests of the high-speed interface circuit 104 that interfaces by the high-speed signal, the transmission and reception characteristics of the driver, the receiver and the like of the high-speed interface circuit 112 of the reference LSI 108 which is the object of the transmission and reception of the LSI under test 101 can be arbitrarily changed from the outside and a plurality of high-speed signal transmission conditions can be set by arbitrarily switching, from the outside, among a plurality of kinds of high-speed-interface-specific cables being provided, so that a difficult condition for the LSI under test 101 to perform the transmission or reception of the high-speed signal can be created.

Moreover, since the test can be realized by the interface of only the low-speed signal with the LSI tester 102, the mass production test of the high-speed interface can be realized only by an inexpensive LSI tester that interfaces at low speed and the high-speed interface circuit test module 400 of the simple structure disposed on the load board 103, so that the test cost can be prevented from increasing.

Moreover, by making the high-speed interface circuit test module 400 disconnectable from the load board 103 by the second connector 109 for low-speed signal communication, the high-speed interface circuit test module 400 can be used for various kinds of LSI testers.

While the present embodiment is described with the focus placed on the transmission and reception tests of the high-speed interface circuit 104, by connecting all the pins except the high-speed pin of the LSI under test to the LSI tester 102, the function test of other circuits and the DC test of leakage current or the like can be performed when LSIs are mass-produced.

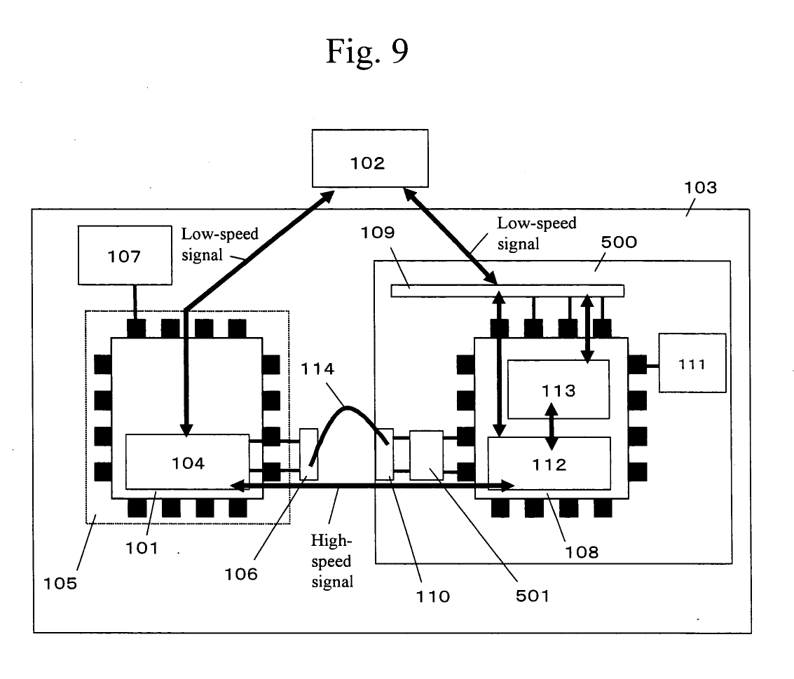

A fifth embodiment of the present invention will be described with reference to FIG. 9. As the fifth embodiment, an embodiment according to claims 13, 14 and 15 will be described. FIG. 9 shows the structure of an LSI test using a high-speed interface circuit test module 500 according to the fifth embodiment of the present invention. Circuits having the same functions as those of the first embodiment are denoted by the same reference numerals.

The structure of this embodiment is different from that of the first embodiment in that a filter or jitter injector 501 capable of changing the high-speed signal transmission characteristic is newly provided on the high-speed interface circuit test module 500.

The filter or jitter injector 501 has its one end connected to both or either of the high-speed signal input terminal and the high-speed signal output terminal of the reference LSI 108 and has its other end connected to the first connector 110 provided specifically for the high-speed interface. To make the high-speed signal transmission characteristic of the filter or jitter injector 501 variable, a control signal port of the second connector for low-speed signal communication may be provided and connected to the filter or jitter injector 501 (the structure according to claim 14), or a fixed switch may be provided on the high-speed interface circuit test module 500 to control the filter or jitter injector 501 (the structure according to claim 15).

The power supply to the devices is performed from the LSI tester 102 (the above-described is the structure according to claim 13).

Next, an LSI test method using the high-speed interface circuit test module 500 of the embodiment of the present invention will be described. Although the LSI control flow is as shown in any of FIGS. 2, 3, 4 and 5, it is somewhat different from that of the first embodiment in that a control for the setting of the filter or jitter injector 501 is added.

First, a reception test of the high-speed interface circuit 104 of the LSI under test 101 will be described. The control flow of this test is similar to that of FIG. 2. This test method is different from that of the first embodiment in that the control for the setting of the filter or jitter injector 501 is included.

A predetermined test voltage is supplied from the LSI tester 102 to the power terminals and the input terminals of the LSI under test 101 and the reference LSI 108 (S1), and a reset signal is supplied. Moreover, the clock signal is supplied to the LSI under test 101 and the reference LSI 108 by the clock generator 107 and the clock generator 111 (S2). The clock signal may be supplied from the LSI tester 102 by way of the load board 103 and the second connector 109 for low-speed signal communication. Then, the high-speed interface circuit 104 of the LSI under test 101 and the high-speed interface circuit 112 of the reference LSI 108 on the high-speed interface circuit test module 500 are accessed from the LSI tester 102 by the low-speed signal, and the reception setting and the transmission setting are made thereon (S3). Moreover, for the characteristic control register circuit 113, a desired register setting is made on the characteristic control register circuit 113 by the input of the control signal from the LSI tester 102, by the input of the control signal by the fixed switching circuit, or by use of the set values of the transmission and reception characteristics of the initial condition of the characteristic control register circuit 113 without any external control, whereby the transmission characteristic of the driver circuit of the high-speed interface circuit 112 is set so as to be changed (S4). For example, the amplitude of the voltage which is the output signal from the driver is increased or decreased by changing the output current amount of the driver circuit, or the following setting is made: the setting to shift the common mode level intermediate between the high level and the low level from the ideal potential; or the setting where the transmitting end resistance of the driver is variable and signal reflection readily occurs due to an impedance mismatch. This enables the creation of a condition under which it is difficult for the receiver circuit of the high-speed interface circuit 104 of the LSI under test 101 to receive the high-speed signal. The transmission setting of the high-speed interface circuit 112 and the transmission characteristic setting to the characteristic control register circuit 113 may be controlled by use of the communication protocol interface circuit. Moreover, the transmission characteristic of the high-speed signal is changed by the filter or jitter injector 501 disposed on the high-speed signal transmission line. For example, the amplitude of the transmission signal is reduced by allowing the transmission signal to pass by use of an attenuator which is a kind of filter. Moreover, a jitter component is provided to the clock characteristic (frequency component) of the high-speed signal by allowing the transmission signal to pass by use of the jitter injector (the method by the structure according to claim 13). Moreover, the characteristic value of the filter or jitter injector 501 may be arbitrarily set from the outside by the control signal from the LSI tester (the method by the structure according to claim 14). Further, the characteristic value of the filter or jitter injector 501 may be arbitrarily set by the control from the fixed switch constructed on the high-speed interface circuit test module 500 (the method by the structure according to claim 15). By degrading the high-speed signal transmission characteristic by the above-described method, a difficult condition for the receiver circuit of the high-speed interface circuit 104 of the LSI under test 101 to receive the high-speed signal can be created.

Then, a test pattern of the low-speed signal for data transmission is inputted from the LSI tester 102 to the reference LSI 108 (S5). The test pattern for data transmission is converted into the high-speed signal by serializing or the like at the high-speed interface circuit 112 of the reference LSI 108, and the high-speed signal is transmitted from the driver circuit (S6). The high-speed signal passes through the first connector 110 provided specifically for the high-speed interface, the high-speed-interface-specific cable 114 and the third connector 106 provided specifically for the high-speed interface to be inputted to the input terminal of the LSI under test 101. That is, the receiver circuit of the high-speed interface circuit 104 of the LSI under test 101 receives the data of the high-speed signal. The received high-speed signal is converted into the low-speed signal by deserializing or the like at the high-speed interface circuit 104. The LSI tester 102 reads out the reception data converted into the low-speed signal of the high-speed interface circuit 104 (S7). It is necessary for the LSI tester 102 to capture data into the memory of the LSI tester 102 in synchronism with the output timing of the reception data of the LSI under test 101, and as an example, the synchronism is obtained by use of the function of matching the output data with the expected value and the function of capturing digital data into the memory in a predetermined cycle which are functions of the LSI tester. When a FIFO circuit is present within the LSI under test 101, synchronism with the LSI tester is obtained by converting the output timing of the reception data inputted to the FIFO circuit so that the reception data is in synchronism with the external clock, that is, the clock of the LSI tester 102. Lastly, the reception data is compared with the expected value by the LSI tester 102, and it is determined whether the reception test of the LSI under test 101 is good or not (S8).

Next, a transmission test of the high-speed interface circuit 104 of the LSI under test 101 will be described. The control flow of this test is similar to that of FIG. 3. This test method is different from that of the first embodiment in that the control for the setting of the filter or jitter injector 501 is included.

A predetermined test voltage is supplied from the LSI tester 102 to the power terminals and the input terminals of the LSI under test 101 and the reference LSI 108 (S1), and a reset signal is supplied. Moreover, the clock signal is supplied to the LSI under test 101 and the reference LSI 108 by the clock generator 107 and the clock generator 111 (S2). The clock signal may be supplied from the LSI tester 102 by way of the load board 103 and the second connector 109 for low-speed signal communication. Then, the high-speed interface circuit 104 of the LSI under test 101 and the high-speed interface circuit 112 of the reference LSI 108 on the high-speed interface circuit test module 500 are accessed from the LSI tester 102 by the low-speed signal, and the transmission setting and the reception setting are made thereon (S3). Moreover, for the characteristic control register circuit 113, a desired register setting is made on the characteristic control register circuit 113 by the input of the control signal from the LSI tester 102, by the input of the control signal by the fixed switching circuit, or by use of the set values of the transmission and reception characteristics of the initial condition without any external control, whereby the reception characteristic of the driver circuit of the high-speed interface circuit 112 is set so as to be changed (S4). For example, the following setting is made: the setting to decrease the amplitude of the voltage that can be received by the receiver by changing the detection current value and the detection reference voltage value of the receiver circuit; the setting to shift the common mode voltage intermediate between the high level and the low level from the ideal potential by changing the amount of pull-in current of the receiver circuit; or the setting where the terminating resistance of the receiver is variable and signal reflection readily occurs due to an impedance mismatch. This enables the creation of a condition under which it is difficult for the driver circuit of the high-speed interface circuit 104 of the LSI under test 101 to transmit the high-speed signal. The reception setting of the high-speed interface circuit 112 and the reception characteristic setting to the characteristic control register circuit 113 may be controlled by use of the communication protocol interface circuit. Moreover, the transmission characteristic of the high-speed signal is changed by the filter or jitter injector 501 disposed on the high-speed signal transmission line. For example, the amplitude of the reception signal is reduced by allowing the reception signal to pass by use of an attenuator which is a kind of filter. Moreover, a jitter component is provided to the clock characteristic (frequency component) of the high-speed signal by allowing the reception signal to pass by use of the jitter injector (the method by the structure according to claim 13). Moreover, the characteristic value of the filter or jitter injector 501 may be arbitrarily set from the outside by the control signal from the LSI tester (the method by the structure according to claim 14). Further, the characteristic value of the filter or jitter injector 501 may be set by the control from the fixed switch constructed on the high-speed interface circuit test module 500 (the method by the structure according to claim 15). By degrading the high-speed signal transmission characteristic by the above-described method, a difficult condition for the receiver circuit of the high-speed interface circuit 104 of the LSI under test 101 to transmit the high-speed signal can be created.

Then, a test pattern of the low-speed signal for data transmission is inputted from the LSI tester 102 to the LSI under test 101 (S5). The test pattern for data transmission is converted into the high-speed signal by serializing or the like at the high-speed interface circuit 104 of the LSI under test 101, and the high-speed signal is transmitted from the driver circuit (S6). The high-speed signal passes through the third connector 106 provided specifically for the high-speed interface, the high-speed-interface-specific cable 114 and the first connector 110 provided specifically for the high-speed interface to be inputted to the input terminal of the reference LSI 108. That is, the receiver circuit of the high-speed interface circuit 112 of the reference LSI 108 receives the data of the high-speed signal. The received high-speed signal is converted into the low-speed signal by deserializing or the like at the high-speed interface circuit 112. The LSI tester 102 reads out the reception data converted into the low-speed signal of the high-speed interface circuit 112 (S7). By a method such as the above-described reception data capturing method by the functions of the LSI tester 102 or the like, data is captured into the memory of the LSI tester 102 in synchronism with the output timing of the reception data of the high-speed interface circuit 112. Lastly, the reception data is compared with the expected value by the LSI tester 102, and it is determined whether the transmission test of the LSI under test 101 is good or not (S8).

Embodiments for FIGS. 4 and 5 are omitted because the contents associated with the use of the high-speed-interface-specific cable 114 and the second cable 403 provided specifically for the high-speed interface which contents are newly described in the present embodiment are the same as those described above.

As described above, by using the high-speed interface circuit test module 500 provided with the filter or jitter injector 501 like the structure according to claim 13 of the present invention, in the transmission and reception tests of the high-speed interface circuit 104 that interfaces by the high-speed signal, the transmission and reception characteristics of the driver, the receiver and the like of the high-speed interface circuit 112 of the reference LSI 108 which is the object of the transmission and reception of the LSI under test 101 can be arbitrarily changed from the outside and the transmission characteristic of the high-speed signal can be arbitrarily set from the outside by the filter or jitter injector 501 disposed on the high-speed signal transmission line, so that a difficult condition for the LSI under test 101 to perform the transmission or reception of the high-speed signal can be created.

Moreover, by changing the characteristic value of the filter or jitter injector 501 from the LSI tester 102 like the structure according to claim 14, the characteristic evaluation of the high-speed transmission and reception tests can be performed under various conditions. Then, by the control from the LSI tester 102, the test can be performed under a plurality of kinds of difficult conditions.

Moreover, by changing the characteristic value of the filter or jitter injector 501 by controlling the fixed switch on the high-speed interface circuit test module 500 like the structure according to claim 15, the characteristic evaluation of the high-speed transmission and reception tests can be performed under various conditions. Then, by switching the fixed switch after determining the most suitable high-speed signal transmission characteristic, the test condition can be set. Moreover, the control signal from the LSI tester 102 is unnecessary, so that the test time can be reduced although the reduction amount is slight.

Further, since the test can be realized by the interface of only the low-speed signal with the LSI tester 102, the mass production test of the high-speed interface can be realized only by an inexpensive LSI tester that interfaces at low speed and the high-speed interface circuit test module 500 of the simple structure disposed on the load board 103, so that the test cost can be prevented from increasing.

Moreover, by making the high-speed interface circuit test module 500 disconnectable from the load board 103 by the second connector 109 for low-speed signal communication, the high-speed interface circuit test module 500 can be used for various kinds of LSI testers.

While the present embodiment is described with the focus placed on the transmission and reception tests of the high-speed interface circuit 104, by connecting all the pins except the high-speed pin of the LSI under test to the LSI tester 102, the function test of other circuits and the DC test of leakage current or the like can be performed when LSIs are mass-produced.

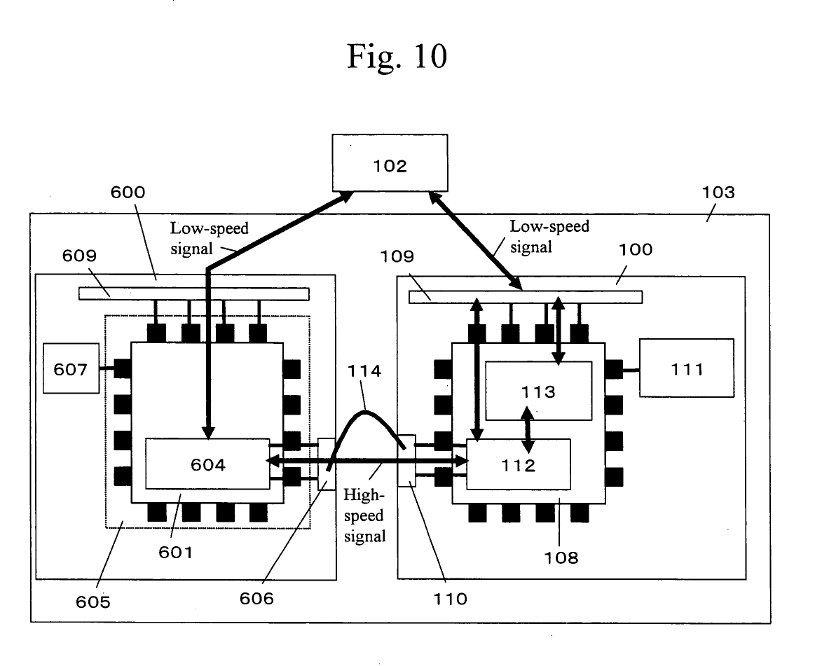

A sixth embodiment of the present invention will be described with reference to FIG. 10. As the sixth embodiment, an embodiment according to claims 16 and 17 will be described. FIG. 10 shows the structure of an LSI test using a module under high-speed interface circuit test 600 according to the sixth embodiment of the present invention. Circuits having the same functions as those of the first embodiment are denoted by the same reference numerals.

The structure of this embodiment is different from that of the first embodiment in that an LSI under test 601, an LSI socket 605, a clock generator 607, a third connector 606 provided specifically for the high-speed interface, a fourth connector 609 for low-speed signal communication and the module under high-speed interface circuit test 600 for disposing them are newly provided on the load board 103.

The module under high-speed interface circuit test 600 is disposed on the load board 103, and is provided with the LSI under test 601, the LSI socket 605, the fourth connector 609 for low-speed signal communication that is connected to the load board 103 and exchanges the low-speed signal with the LSI tester 102, the third connector 606 provided specifically for the high-speed interface for transmitting the high-speed signal to the outside, and the clock generator 607 that generates the clock supplied to the LSI under test 601.

The LSI under test 601 is provided with a high-speed interface circuit 602 having circuits such as a driver circuit and a receiver circuit for the high-speed signal interfacing with the outside of the LSI at high speed and a serializer and a deserializer that convert the signal speed between the high-speed signal and the low-speed signal. The LSI under test 601 is connected to the module under high-speed interface circuit test 600 through an LSI socket 605 disposed on the module under high-speed interface circuit test 600. The fourth connector 609 for low-speed signal communication connects the load board 103 and the module under high-speed interface circuit test 600 together, and is provided with a signal port and a power port that are necessary for the access of the LSI tester 102 and the high-speed interface circuit 602 by the low-speed signal. The third connector 606 provided specifically for the high-speed interface is connected to the high-speed signal input and output terminals of the LSI under test 601 through pattern wiring. Then, the first connector 110 provided specifically for the high-speed interface disposed on the high-speed interface circuit test module 100 and the third connector 606 provided specifically for the high-speed interface are connected together by the high-speed-interface-specific cable 114. This connects the high-speed signal input and output terminals of the LSI under test 601 and the high-speed signal input and output terminals of the reference LSI 108 together. The clock generator 607 is connected to the clock input terminal of the LSI under test 601 to supply the clock signal. Instead of providing the clock generator 607, the clock signal may be supplied from the LSI tester 102 by providing a clock supply port on the fourth connector 604 for low-speed signal communication. A relay for switching the connection direction may be provided in the connection between the high-speed signal input and output terminals and the third connector 606 provided specifically for the high-speed interface so that the high-speed signal input and output terminals and the fourth connector 601 for low-speed signal communication are connected together (the structure according to claim 17).

The power supply to the devices is performed from the LSI tester 102 (the above-described is the structure according to claim 16).

An LSI test method using the module under high-speed interface circuit test 600 of the embodiment of the present invention is similar to that of the first embodiment, and the LSI control flow is as shown in any of FIGS. 2, 3, 4 and 5.

As described above, by adopting the structure according to claim 16, the module under high-speed interface circuit test 600 can be made disconnectable from the load board 103 by the fourth connector 609 for low-speed signal communication. Generally, a board including a high-speed signal transmission line is inferior in yield, and a man-hour for debugging the board occurs. While according to the embodiments 1 to 5, an LSI tester is used for the board debugging, according to the present structure, it is not always necessary to use an LSI tester; the board can be debugged by use of a simple jig or measuring instrument. For this reason, the board debugging can be performed without the use of an expensive LSI tester, the high-speed signal transmission and reception tests can be efficiently debugged and analyzed. Moreover, since a high-speed signal transmission line can be formed on the module under high-speed interface circuit test 600 and the high-speed interface circuit test module 100 for the inferiority of the yield of the board including a high-speed signal transmission line, compared to when the high-speed signal transmission line is formed on the load board 103, the cost of the board when the yield of the board is inferior can be reduced.

Moreover, since the connector to which the high-speed signal input and output terminals of the LSI under test 601 can be switched to the fourth connector 609 for low-speed signal communication like the structure according to claim 17, the DC test on the high-speed signal input and output terminals and the test by the low-speed signal can be performed by the LSI tester 102. Generally, when the number of test processes increases, the test cost increases; however, by using the present structure, both of the high-speed signal transmission and reception tests and another test such as the DC test or the low-speed signal test can be performed on the LSI under test 606 through one process, so that the test cost can be suppressed.

While the present embodiment is described with the focus placed on the transmission and reception tests of the high-speed interface circuit 104, by connecting all the pins except the high-speed pin of the LSI under test to the LSI tester 102, the function test of other circuits and the DC test of leakage current or the like can be performed when LSIs are mass-produced.

The present embodiment is applicable to the test of the high-speed interface circuits of IEEE 1394, USB, Serial-ATA and the like. For example, in the test of an LSI provided with Serial-ATA 1.0a, with respect to the signal speed 1.5 Gbps of the high-speed interface part, by a method such that the transmission and reception data speed-converted into the low-speed signal by the high-speed interface circuit is temporarily stored in the memory of the LSI or the like, the test can be realized with the operating frequency of the LSI tester not more than several Mbps or several kbps. Consequently, the mass production test can be realized by an inexpensive LSI tester without the use of an expensive LSI tester capable of interfacing at 1.5 Gbps.

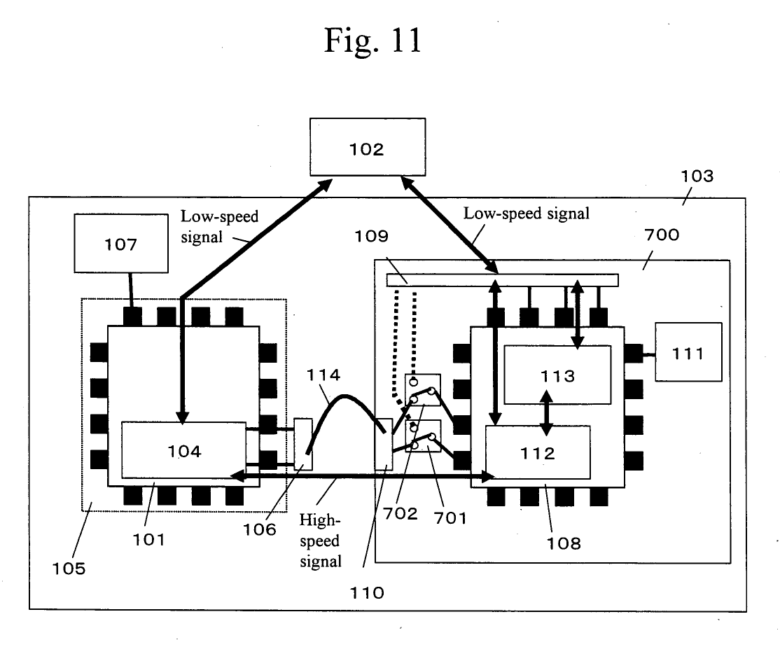

A seventh embodiment of the present invention will be described with reference to FIGS. 11 to 13. As the seventh embodiment, an embodiment according to claims 12, 26 and 27 will be described. FIG. 11 shows the structure of an LSI test using a high-speed interface circuit test module 700 according to the seventh embodiment of the present invention. Circuits having the same functions as those of the first embodiment are denoted by the same reference numerals.

The structure of this embodiment is different from that of the first embodiment in that a first relay 701 and a second relay 702 are newly provided between the high-speed signal input and output terminals of the reference LSI and the first connector 110 provided specifically for the high-speed interface on the high-speed interface circuit test module 700.

The first relay 701 has its one end connected to the high-speed signal input terminal of the reference LSI 108 and has its other end connected to both the first connector 110 provided specifically for the high-speed interface and the second connector 109 for low-speed signal communication. Moreover, the second relay 702 has its one end connected to the high-speed signal output terminal of the reference LSI 108 and has its other end connected to both of the first connector 110 provided specifically for the high-speed interface and the second connector 109 for low-speed signal communication. The second connector 109 for low-speed signal communication is provided with a signal port for inputting and outputting signals from the first relay 701 and the second relay 702 and a control signal port for switching the signal directions of the first relay 701 and the second relay 702.

The power supply to the devices is performed from the LSI tester 102 (the above-described is the structure according to claim 12).

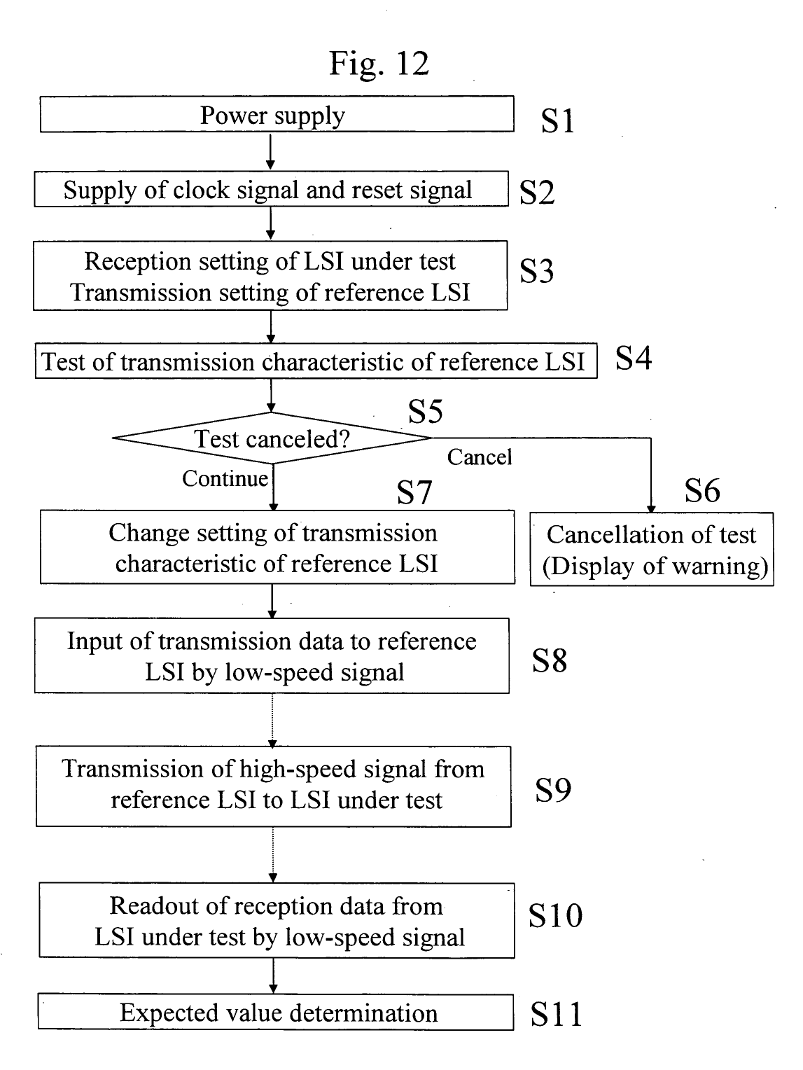

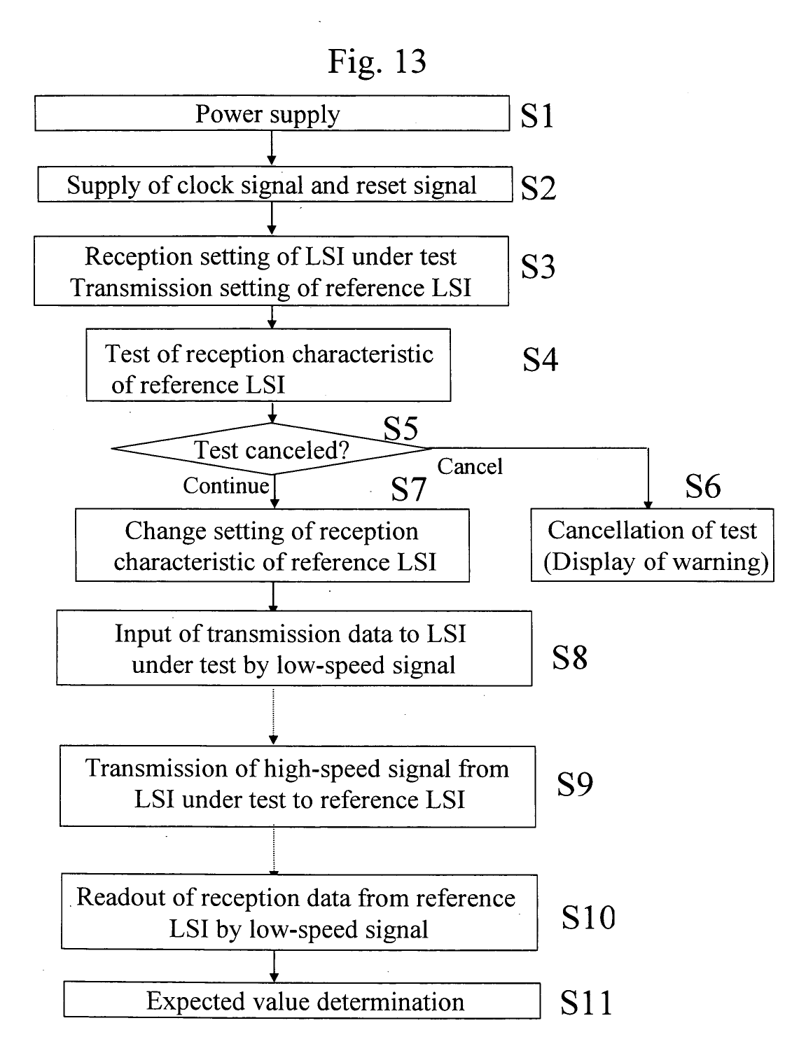

Next, an LSI test method using the high-speed interface circuit test module 700 of the embodiment of the present invention will be described. The LSI control flow is as shown in any of FIGS. 12 and 13.

First, a reception test of the high-speed interface circuit 104 of the LSI under test 101 will be described. FIG. 12 is the control flow of the test according to the seventh embodiment of the present invention. This test method is different from that of the first embodiment in that the test of the transmission characteristic of the reference LSI 108, the determination as to whether to cancel or continue the test and the control for the setting of the first relay 701 and the second relay 702 are included.

A predetermined test voltage is supplied from the LSI tester 102 to the power terminals and the input terminals of the LSI under test 101 and the reference LSI 108 (S1), and a reset signal is supplied. Moreover, the clock signal is supplied to the LSI under test 101 and the reference LSI 108 by the clock generator 107 and the clock generator 111 (S2). The clock signal may be supplied from the LSI tester 102 by way of the load board 103 and the second connector 109 for low-speed signal communication. Then, the high-speed interface circuit 104 of the LSI under test 101 and the high-speed interface circuit 112 of the reference LSI 108 on the high-speed interface circuit test module 700 are accessed from the LSI tester 102 by the low-speed signal, and the reception setting and the transmission setting are made thereon (S3). Then, by controlling the first relay 701 and the second relay 702 by the control signal from the LSI tester 102, the connection direction is switched so that signals of the high-speed signal input and output terminals of the reference LSI 108 can be exchanged with the second connector 109 for low-speed signal communication. Then, by connecting the LSI tester 102 and the high-speed signal input and output terminals together and performing the signal input and output by the DC voltage amount and current amount and the low-speed signal, the basic characteristics of the driver circuit are tested (S4). For example, the output current amount, the bias voltage, the transmitting end resistance and the like of the driver are measured. At this time, it is determined whether or not the measured transmission characteristics satisfy the characteristics necessary for performing the high-speed transmission and reception tests (S5) When it is determined that the result of the transmission characteristic measurement is abnormal, it is determined that the reference LSI 108 is out of order or abnormal, and the succeeding high-speed transmission and reception tests are canceled and an alarm is displayed (S6). When it is determined that the result of the transmission characteristic measurement is normal, the succeeding processing is performed (the method according to claim 27).

Then, for the characteristic control register circuit 113, a desired register setting is made on the characteristic control register circuit 113 by the input of the control signal from the LSI tester 102, by the input of the control signal by the fixed switching circuit, or by use of the set values of the transmission and reception characteristics of the initial condition of the characteristic control register circuit 113 without any external control, whereby the transmission characteristic of the driver circuit of the high-speed interface circuit 112 is set so as to be changed (S7). For example, the amplitude of the voltage which is the output signal from the driver is increased or decreased by changing the output current amount of the driver circuit, or the following setting is made: the setting to shift the common mode level intermediate between the high level and the low level from the ideal potential; or the setting where the transmitting end resistance of the driver is variable and signal reflection readily occurs due to an impedance mismatch. At this time, by using as the reference value the measurement result of the transmission characteristics of the high-speed signal input and output terminals of the reference LSI 108 measured in real time, the amount of change from the reference value is set. This enables the creation of a condition under which it is difficult for the receiver circuit of the high-speed interface circuit 104 of the LSI under test 101 to receive the high-speed signal. Moreover, since the change amount is determined based on the transmission characteristics measured in real time, the transmission characteristics which are test conditions are accurately set. The transmission setting of the high-speed interface circuit 112 and the transmission characteristic setting to the characteristic control register circuit 113 may be controlled by use of the communication protocol interface circuit.

Then, a test pattern of the low-speed signal for data transmission is inputted from the LSI tester 102 to the reference LSI 108 (S8). The test pattern for data transmission is converted into the high-speed signal by serializing or the like at the high-speed interface circuit 112 of the reference LSI 108, and the high-speed signal is transmitted from the driver circuit (S9). The high-speed signal passes through the first connector 110 provided specifically for the high-speed interface, the high-speed-interface-specific cable 114 and the third connector 106 provided specifically for the high-speed interface to be inputted to the input terminal of the LSI under test 101. That is, the receiver circuit of the high-speed interface circuit 104 of the LSI under test 101 receives the data of the high-speed signal. The received high-speed signal is converted into the low-speed signal by deserializing or the like at the high-speed interface circuit 104. The LSI tester 102 reads out the reception data converted into the low-speed signal of the high-speed interface circuit 104 (S10). It is necessary for the LSI tester 102 to capture data into the memory of the LSI tester 102 in synchronism with the output timing of the reception data of the LSI under test 101, and as an example, the synchronism is obtained by use of the function of matching the output data with the expected value and the function of capturing digital data into the memory in a predetermined cycle which are functions of the LSI tester. When a FIFO circuit is present within the LSI under test 101, synchronism with the LSI tester is obtained by converting the output timing of the reception data inputted to the FIFO circuit so that the reception data is in synchronism with the external clock, that is, the clock of the LSI tester 102. Lastly, the reception data is compared with the expected value by the LSI tester 102, and it is determined whether the reception test of the LSI under test 101 is good or not (S11).

Next, a transmission test of the high-speed interface circuit 104 of the LSI under test 101 will be described. FIG. 7 is the control flow of another test according to the seventh embodiment of the present invention. This test method is different from that of the first embodiment in that the test of the reception characteristic of the reference LSI 108, the determination as to whether to cancel or continue the test and the control for the setting of the first relay 701 and the second relay 702 are included.

A predetermined test voltage is supplied from the LSI tester 102 to the power terminals and the input terminals of the LSI under test 101 and the reference LSI 108 (S1), and a reset signal is supplied. Moreover, the clock signal is supplied to the LSI under test 101 and the reference LSI 108 by the clock generator 107 and the clock generator 111 (S2). The clock signal may be supplied from the LSI tester 102 by way of the load board 103 and the second connector 109 for low-speed signal communication. Then, the high-speed interface circuit 104 of the LSI under test 101 and the high-speed interface circuit 112 of the reference LSI 108 on the high-speed interface circuit test module 700 are accessed from the LSI tester 102 by the low-speed signal, and the transmission setting and the reception setting are made thereon (S3). Then, by controlling the first relay 701 and the second relay 702 by the control signal from the LSI tester 102, the connection direction is switched so that signals of the high-speed signal input and output terminals of the reference LSI 108 can be exchanged with the second connector 109 for low-speed signal communication. Then, by connecting the LSI tester 102 and the high-speed signal input and output terminals together and performing the signal input and output by the DC voltage amount and current amount and the low-speed signal, the basic characteristics of the receiver circuit are tested (S4). For example, the pull-in current amount, the bias voltage, the terminating resistance and the like of the receiver circuit are measured. At this time, it is determined whether or not the measured reception characteristics satisfy the characteristics necessary for performing the high-speed transmission and reception tests (S5) When it is determined that the result of the reception characteristic measurement is abnormal, it is determined that the reference LSI 108 is out of order or abnormal, and the succeeding high-speed transmission and reception tests are canceled and an alarm is displayed (S6). When it is determined that the result of the transmission characteristic measurement is normal, the succeeding processing is performed (the method according to claim 27).

Then, for the characteristic control register circuit 113, a desired register setting is made on the characteristic control register circuit 113 by the input of the control signal from the LSI tester 102, by the input of the control signal by the fixed switching circuit, or by use of the set values of the transmission and reception characteristics of the initial condition without any external control, whereby the reception characteristic of the driver circuit of the high-speed interface circuit 112 is set so as to be changed (S7). For example, the following setting is made: the setting to decrease the amplitude of the voltage that can be received by the receiver by changing the detection current value and the detection reference voltage value of the receiver circuit; the setting to shift the common mode voltage intermediate between the high level and the low level from the ideal potential by changing the amount of pull-in current of the receiver circuit; or the setting where the terminating resistance of the receiver is variable and signal reflection readily occurs due to an impedance mismatch. At this time, by using as the reference value the measurement result of the reception characteristics of the high-speed signal input and output terminals of the reference LSI 108 measured in real time, the amount of change from the reference value is set. This enables the creation of a condition under which it is difficult for the driver circuit of the high-speed interface circuit 104 of the LSI under test 101 to transmit the high-speed signal. Moreover, since the change amount is determined based on the reception characteristics measured in real time, the reception characteristics which are test conditions are accurately set. The reception setting of the high-speed interface circuit 112 and the reception characteristic setting to the characteristic control register circuit 113 may be controlled by use of the communication protocol interface circuit.

Then, a test pattern of the low-speed signal for data transmission is inputted from the LSI tester 102 to the LSI under test 101 (S8). The test pattern for data transmission is converted into the high-speed signal by serializing or the like at the high-speed interface circuit 104 of the LSI under test 101, and the high-speed signal is transmitted from the driver circuit (S9). The high-speed signal passes through the third connector 106 provided specifically for the high-speed interface, the high-speed-interface-specific cable 114 and the first connector 110 provided specifically for the high-speed interface to be inputted to the input terminal of the reference LSI 108. That is, the receiver circuit of the high-speed interface circuit 112 of the reference LSI 108 receives the data of the high-speed signal. The received high-speed signal is converted into the low-speed signal by deserializing or the like at the high-speed interface circuit 112. The LSI tester 102 reads out the reception data converted into the low-speed signal of the high-speed interface circuit 112 (S10). By a method such as the above-described reception data capturing method by the functions of the LSI tester 102 or the like, data is captured into the memory of the LSI tester 102 in synchronism with the output timing of the reception data of the high-speed interface circuit 112. Lastly, the reception data is compared with the expected value by the LSI tester 102, and it is determined whether the transmission test of the LSI under test 101 is good or not (S11) (the above-described is the method according to claim 26).

As described above, by testing the high-speed signal input and output terminals of the reference LSI 108 by the LSI tester 102 before performing the high-speed transmission and reception tests like the structure according to claim 12 of the present invention and the method according to claim 26, the change amount is set with respect to a reference value by using as the reference value the measurement result of the driver circuit and the receiver circuit of the high-speed signal input and output terminals of the reference LSI 108, and the change of desired transmission characteristics and reception characteristics for performing the high-speed signal transmission and reception tests can be set. For this reason, in a case where a plurality of reference LSIs 108 are used when the reference LSI 108 is changed to another chip or when the test is performed by a plurality of LSI testers 102, irrespective of which reference LSI 108 is selected, the transmission characteristics and the reception characteristics can be set to similar characteristic values at the time of the high-speed signal transmission and reception tests, and it is unnecessary to change the setting of the control from the LSI tester 102, that is, the test program every time the reference LSI 108 is changed. Moreover, even when a slight characteristic change occurs in the driver and receiver circuits through long-term use of the reference LSI 108, since the change amount of the characteristic value can be set with the characteristic result measured in real time as the reference, a difficult condition for the LSI under test 101 to perform the transmission or reception of the high-speed signal can be accurately set, so that quality can be ensured.

Moreover, since the high-speed signal input and output terminals of the reference LSI 108 are tested by the LSI tester 102 before performing the high-speed transmission and reception tests and a quality determination as to whether the high-speed interface circuit 112 of the reference LSI 108 is out of order or not can be made based on the result like the structure according to claim 12 of the present invention and the method according to claim 27, it can be determined that the execution of the high-speed signal transmission and reception tests is canceled or that the reference LSI 108 is changed to another chip, so that the test quality and maintainability can be ensured.

Further, since the test can be realized by the interface of only the low-speed signal with the LSI tester 102, the mass production test of the high-speed interface can be realized only by an inexpensive LSI tester that interfaces at low speed and the high-speed interface circuit test module 500 of the simple structure disposed on the load board 103, so that the test cost can be prevented from increasing.

Moreover, by making the high-speed interface circuit test module 100 disconnectable from the load board 103 by the second connector 109 for low-speed signal communication, the high-speed interface circuit test module 100 can be used for various kinds of LSI testers.

While the present embodiment is described with the focus placed on the transmission and reception tests of the high-speed interface circuit 104, by connecting all the pins except the high-speed pin of the LSI under test to the LSI tester 102, the function test of other circuits and the DC test of leakage current or the like can be performed when LSIs are mass-produced.

While the following connectors are used in the above-described first to seventh embodiments: the first connector 110 provided specifically for the high-speed interface and the second connector 109 for low-speed signal communication which connectors 110 and 109 are connected to the reference LSI 108; and the third connector 106 provided specifically for the high-speed interface and the fourth connector 609 for low-speed signal communication which connectors 106 and 609 are connected to the LSI under test 101 and the LSI under test 601, instead of these connectors, a conductive metal terminal for electric signal input and output may be provided and connected to the high-speed-interface-specific cable 114 and the load board 103 by a metal wire (the structure according to claims 18 and 19).

Further, while the LSI tester 102 is used in the above-described first to seventh embodiments, by disconnecting the high-speed interface circuit test modules 100 to 700 from the load board 103, connecting them to a different board, and using a digital signal input and output device capable of generating and capturing a digital signal and applying power instead of the LSI tester 102, the high-speed signal transmission and reception tests of the LSI under test 101 and the LSI under test 601 can be performed. Moreover, the LSI under test 101 and the LSI under test 601 can be evaluated by using a DC measuring instrument, an oscilloscope, a digitizer or the like without the use of the LSI tester 102 (the structure according to claim 21).

1. A high-speed interface circuit test module comprising:
a high-speed interface circuit that is provided with a circuit converting a signal speed, and is capable of changing transmission and reception characteristics;
a controller that controls the transmission and reception characteristics of the high-speed interface circuit;
a clock generator that generates a clock supplied to the high-speed interface circuit;
a first connector provided specifically for a high-speed interface, connected to the high-speed interface circuit and provided with a signal port for performing high-speed signal communication with a circuit under test; and
a second connector connected to the high-speed interface circuit and the LSI tester and provided with a signal port and a power port for performing low-speed signal communication with the high-speed interface circuit.

2. A high-speed interface circuit test module according to claim 1, wherein the high-speed interface circuit is provided with a test algorithm serving as a procedure by which the high-speed interface is tested.

3. A high-speed interface circuit test module according to claim 1 or 2, wherein a signal port for setting the transmission and reception characteristics of the high-speed interface circuit is provided in the second connector.

4. A high-speed interface circuit test module according to claim 1 or 2, comprising a fixed switch for setting the transmission and reception characteristics of the high-speed interface circuit.

5. A high-speed interface circuit test module according to claim 1 or 2 comprising a serial or parallel interface circuit having a general-purpose communication protocol for performing the low-speed signal communication and change setting of the transmission and reception characteristics.

6. A high-speed interface circuit test module according to claim 1 or 2 wherein instead of the clock generator, a clock supply port is provided in the second connector.

7. A high-speed interface circuit test module according to claim 1 or 2 comprising both or either of a high-speed interface test pattern generator that inputs a pattern to the high-speed interface circuit and a pattern comparator that compares an output from the high-speed interface circuit with an expected value.

8. A high-speed interface circuit test module according to claim 1 or 2, comprising a modulator that modulates the clock supplied to the high-speed interface circuit or a jitter injector that injects jitter to change a clock characteristic.

9. A high-speed interface circuit test module according to claim 8, wherein a signal port for setting the clock characteristic based on a modulation amount and a modulation frequency of the modulator or a jitter amount of the jitter injector is provided in the second connector.

10. A high-speed interface circuit test module according to claim 8, comprising a fixed switch for setting the clock characteristic based on a modulation amount and a modulation frequency setting of the modulator or a jitter amount of the jitter injector.

11. A high-speed interface circuit test module according to claim 1 or 2 comprising: a plurality of connectors similar to the first connector provided specifically for the high-speed interface; and a relay that switches connection between the high-speed interface circuit and the connectors, wherein a control signal port for switching the relay is provided in the second connector.

12. A high-speed interface circuit test module according to claim 1 or 2 comprising a relay that switches an object to which a high-speed terminal of the high-speed interface circuit connected to the first connector is connected, wherein an input and output signal port of the high-speed terminal and a control signal port for switching the relay are provided in the second connector.

13. A high-speed interface circuit test module according to claim 1 or 2, wherein a filter or jitter injector that changes a high-speed signal transmission characteristic is provided between the high-speed interface circuit and the first connector.

14. A high-speed interface circuit test module according to claim 13, wherein a signal port for setting the high-speed signal transmission characteristic is provided in the second connector.

15. A high-speed interface circuit test module according to claim 13, comprising a fixed switch for setting the high-speed signal transmission characteristic.

16. A module under high-speed interface circuit test comprising:
a circuit under test being independent of the high-speed interface circuit test module according to claim 1 or 2 and including a high-speed interface circuit under test;
a clock generator that generates a clock supplied to the circuit under test;
a third connector provided specifically for a high-speed interface, connected to the circuit under test and provided with a signal port for performing high-speed signal communication with the high-speed interface circuit test module; and
a fourth connector provided with a signal port and a power port connected to all terminals or a given terminal of the circuit under test.

17. A module under high-speed interface circuit test according to claim 16, comprising a relay that switches an object to which a high-speed terminal of the circuit under test connected to the third connector is connected, wherein an input and output signal port of the high-speed terminal of the circuit under test and a control signal port for switching the relay are provided in the fourth connector.

18. A high-speed interface circuit test module according to claim 1 or 2 wherein a conductive metal terminal for electric signal input and output is used instead of the first and second connectors.

19. A module under high-speed interface circuit test according to claim 16, wherein a conductive metal terminal for electric signal input and output is used instead of the third and fourth connectors.

20. A high-speed interface circuit test method comprising:
a step where transmission and reception characteristics, a clock characteristic and a high-speed signal transmission characteristic are set to given values from an LSI tester to the high-speed interface circuit test module according to claim 1 or 2;
a step where input and output of a test low-speed signal and a control signal, and application of power are performed between the high-speed interface circuit test module and the LSI tester;
a step where input and output of a test high-speed signal obtained by converting transmission data by the test low-speed signal into a high-speed signal is performed between an LSI under test and the high-speed interface circuit test module; and
a step where the LSI tester compares reception data obtained by converting the test high-speed signal into a low-speed signal with an expected value, and determines a test result.

21. A high-speed interface circuit test method according to claim 20, wherein a digital signal input and output device capable of generating and capturing a digital signal and applying power is used instead of the LSI tester.

22. A high-speed interface circuit test method according to claim 20, wherein a test is performed by use of the LSI under test or a loopback test circuit of the high-speed interface circuit test module.

23. A high-speed interface circuit test method according to claim 20, wherein the test low-speed signal is generated in the high-speed interface circuit test module or the comparison with the expected value is performed.

24. A high-speed interface circuit test method according to claim 23, wherein all the test low-speed signals and the expected value are previously inputted from the LSI tester before a test, and the test is performed while a necessary signal is switched every test.

25. A high-speed interface circuit test method according to claim 20, wherein the LSI under test and the high-speed interface circuit test module are connected by a plurality of kinds of different cables, and a necessary cable is selected at the time of a test by relay switching control from the LSI tester.

26. A high-speed interface circuit test method according to claim 20, wherein a transmission and reception circuit characteristic of the high-speed interface circuit in the high-speed interface circuit test module is tested at the LSI tester, and transmission and reception characteristics are determined based on a result of the test.

27. A high-speed interface circuit test method according to claim 26, wherein a transmission and reception circuit characteristic of the high-speed interface circuit in the high-speed interface circuit test module is tested at the LSI tester, and whether to continue or cancel the test is determined based on a result of the test.

28. A high-speed interface circuit test module according to claim 3, comprising a serial or parallel interface circuit having a general-purpose communication protocol for performing the low-speed signal communication and change setting of the transmission and reception characteristics.

29. A high-speed interface circuit test module according to claim 4, comprising a serial or parallel interface circuit having a general-purpose communication protocol for performing the low-speed signal communication and change setting of the transmission and reception characteristics.

30. A high-speed interface circuit test module according to claim 3, wherein instead of the clock generator, a clock supply port is provided in the second connector.

31. A high-speed interface circuit test module according to claim 4, wherein instead of the clock generator, a clock supply port is provided in the second connector.

32. A high-speed interface circuit test module according to claim 3, comprising both or either of a high-speed interface test pattern generator that inputs a pattern to the high-speed interface circuit and a pattern comparator that compares an output from the high-speed interface circuit with an expected value.

33. A high-speed interface circuit test module according to claim 4, comprising both or either of a high-speed interface test pattern generator that inputs a pattern to the high-speed interface circuit and a pattern comparator that compares an output from the high-speed interface circuit with an expected value.

34. A high-speed interface circuit test module according to claim 3, comprising: a plurality of connectors similar to the first connector provided specifically for the high-speed interface; and a relay that switches connection between the high-speed interface circuit and the connectors, wherein a control signal port for switching the relay is provided in the second connector.

35. A high-speed interface circuit test module according to claim 4, comprising: a plurality of connectors similar to the first connector provided specifically for the high-speed interface; and a relay that switches connection between the high-speed interface circuit and the connectors, wherein a control signal port for switching the relay is provided in the second connector.

36. A high-speed interface circuit test module according to claim 3, comprising a relay that switches an object to which a high-speed terminal of the high-speed interface circuit connected to the first connector is connected, wherein an input and output signal port of the high-speed terminal and a control signal port for switching the relay are provided in the second connector.

37. A high-speed interface circuit test module according to claim 4, comprising a relay that switches an object to which a high-speed terminal of the high-speed interface circuit connected to the first connector is connected, wherein an input and output signal port of the high-speed terminal and a control signal port for switching the relay are provided in the second connector.

38. A high-speed interface circuit test module according to claim 3, wherein a conductive metal terminal for electric signal input and output is used instead of the first and second connectors.

39. A high-speed interface circuit test module according to claim 4, wherein a conductive metal terminal for electric signal input and output is used instead of the first and second connectors.

40. A module under high-speed interface circuit test according to claim 17, wherein a conductive metal terminal for electric signal input and output is used instead of the third and fourth connectors.

41. A high-speed interface circuit test method according to claim 21, wherein a test is performed by use of the LSI under test or a loopback test circuit of the high-speed interface circuit test module.

42. A high-speed interface circuit test method according to claim 21, wherein the LSI under test and the high-speed interface circuit test module are connected by a plurality of kinds of different cables, and a necessary cable is selected at the time of a test by relay switching control from the LSI tester.
